(19) United States
(12) Patent Application Publication
(10) Pub. No.: US 2025/0287768 A1
(43) Pub. Date: Sep. 11, 2025

(54) PEROVSKITE COMPOSITIONS AND USES THEREOF IN PHOTOVOLTAIC DEVICES

(71) Applicant: YISSUM RESEARCH DEVELOPMENT COMPANY OF THE HEBREW UNIVERSITY OF JERUSALEM LTD., Jerusalem (IL)

(72) Inventors: Lioz ETGAR, Jerusalem (IL); Shlomo MAGDASSI, Jerusalem (IL); Pendyala Naresh KUMAR, Jerusalem (IL)

(21) Appl. No.: 18/559,809

(22) PCT Filed: May 12, 2022
(86) PCT No.: PCT/IL2022/050495

§ 371 Date: Nov. 9, 2023

Related U.S. Application Data
(60) Provisional application No. 63/187,586, filed on May 12, 2021.

(51) Int. Cl. H10K 30/40; H10K 85/50

(52) U.S. Cl. CPC H10K 30/40; H10K 85/50

(57) ABSTRACT

The technology generally concerns perovskite-based devices having improved transparency and uses thereof.

### FIELD OF THE INVENTION

The present invention is in the field of transparent or semitransparent photovoltaic devices comprising perovskite compositions.

### BACKGROUND

Metal halide perovskite materials demonstrate a relatively high absorption coefficient, long-range diffusion length, and simple processing techniques which attribute to the rapid development of perovskite solar cells (PSCs). These hybrid materials hold special attention compared to other semiconductors employed in solar cells owing to several distinct properties. Changing the chemical composition of the perovskites can change their optical and physical properties and can also affect their chemical stability [1]. Due to several modifications such as compositional changes, structural alterations and surface-treatments, the power conversion efficiency (PCE) of such solar cells increased from 3.8% to more than 25% within a decade, placing the perovskite-based solar cells as game-changers among other solar cells technologies [2].

Beyond the PCE and device stability, perovskite deposition can be performed at low temperatures by simple solution deposition methods; thus, rendering the perovskites suitable candidates for fabrication of high-efficiency, tandem, flexible, light-weight and semitransparent solar cells [3].

Semitransparency in perovskite solar cells opens the possibility to use them in building-integrated photovoltaics (BIPV) and tandem cells. The most common way to fabricate semitransparent perovskite cells is by alerting their bandgap (perovskite composition) and layer thickness [4]. To date there have been only few reports on new structures of semitransparent PSCs, with moderate PCEs [5]. Among these reports are the de-wetting technique which allows forming a semitransparent perovskite film, but without control over the transparency [6]. According to the de-wetting technique, the solvent is slowly evaporated to slow down the perovskite crystallization process and allow for the formation of discontinuous perovskite islands. This solar cell structure shows a PCE of 6% and average transparency (AVT) of ca. 15% for a full device with 10-nm thick gold top contacts [7]. According to another approach, a SiO₂ honeycomb scaffold template was utilized by combining self-assembly at air-water interface and plasma etching. A porous SiO₂ template was prepared by etching a polystyrene film while filling pores formed with perovskite. The PCE of cells by this technique was 10.3%, and the AVT of the active layer was 38%, measured without the top contacts [8]. An additional approach is based on mesh-assisted perovskite grid deposition method, which enables precise control over the transparency, resulting in a PCE of ˜10% with 28% AVT for a device without top gold contacts [9]. A drawback of this method is the required delicate control of directed wetting, and its sensitivity to various fabrication parameters such as humidity.

### REFERENCES

[1] Yang, T. C. J., Fiala, P., Jeangros, Q. & Ballif, C. High-Bandgap Perovskite Materials for Multijunction Solar Cells. Joule 2, 1421-1436 (2018).
[2] Kojima, A., Teshima, K., Shirai, Y. & Miyasaka, T. Organometal Halide Perovskites as Visible-Light Sensitizers for Photovoltaic. J. Am. Chem. Soc. 131, 6050-6051 (2009).
[3] Jung, H. S., Han, G. S., Park, N. G. & Ko, M. J. Flexible Perovskite Solar Cells. Joule 3, 1850-1880 (2019).
[4] Rold'an-Carmona, C. et al. High efficiency single-junction semitransparent perovskite solar cells. Energy Environ. Sci., 7, 2968-2973 (2014).
[5] Hörantner, M. T. et al. Shunt-Blocking Layers for Semitransparent Perovskite Solar Cells. Adv. Mater. Interfaces 3, 1500837 (1-7) (2016).
[6] Eperon, G. E., Burlakov, V. M., Goriely, A. & Snaith, H. J. Neutral color semitransparent microstructured perovskite solar cells. ACS Nano 8, 591-598 (2014).
[7] Eperon, G. E. et al. Efficient, semitransparent neutral-colored solar cells based on microstructured formamidinium lead trihalide perovskite. J. Phys. Chem. Lett. 6, 129-138 (2015).
[8] Zhang, L., Hörantner, M. T., Zhang, W., Yan, Q. & Snaith, H. J. Near-neutral-colored semitransparent perovskite films using a combination of colloidal self-assembly and plasma etching. Sol. Energy Mater. Sol. Cells 160, 193-202 (2017).
[9] Aharon, S. et al. Self-Assembly of Perovskite for Fabrication of Semitransparent Perovskite Solar Cells. Adv. Mater. Interfaces 2, 1-6 (2015).

### GENERAL DESCRIPTION

Perovskite materials are very efficient semiconducting materials and useful in constructing electrodes in solar cell devices. However, despite of their excellent properties, transparency remains an issue. Despite efforts to increase transparency of perovskite films (e.g., from AVT values below or around 10% to values higher than 20-30%), major improvements in transparencies have not been observed. The inventors of the invention disclosed herein provide a perovskite film having improved transparency, as compared to existing films, due to presence of spaced-apart transparent functionalizable polymeric regions, which extend outwards from the surface of the perovskite film, demonstrating increased transparency and further enable film functionalization.

Thus, in its broadest definition, the invention provides a provision of transparency increase in perovskite-based devices, through formation of polymeric regions or elements or pillars that are formed in the perovskite film or device, which can extend the full thickness of the film or device (e.g., from substrate to topmost surface), and which consequently result in an increase of the AVT values quite significantly.

In a first aspect of the invention there is provided a perovskite film or a device comprising same, which comprises spaced-apart regions or features or islands of at least one functionalizable polymeric material extending outwards from a surface of the perovskite film or device surface (or any layer or a multilayered device). Putting it differently, the invention provides a perovskite film comprising spaced-apart islands (e.g., which in a device comprising same surface extending regions of the perovskite film) of at least one functionalizable polymeric material, wherein the islands are free of a perovskite material, and having a length/height/thickness being at least a thickness of the film.

In some embodiments, the height/length/thickness of the islands refers to their longest axis, being substantially perpendicular to the main axis of the perovskite film. The length/heath/thickness is typically at least the thickness of the perovskite film measured from one face thereof to another.

In some embodiments, the film is a transparent or a semitransparent film, as defined herein. In some embodiments, the film is characterized by an average visible transmittance (AVT) of between 20 and 35% or between 20 and 80%, or at least 12% or at least 20%, as further defined herein.

Also provided is a transparent or a semitransparent perovskite film comprising spaced-apart regions or features of at least one functionalizable polymeric material extending outwards from a surface region of the perovskite film.

Further provided is a perovskite film (i.e., comprising or consisting at least one perovskite material) decorated by spaced-apart polymeric islands or regions which extend thickness of the perovskite film.

The invention further provides a functional element or an article implementing a perovskite film (or layer) of the invention, wherein the spaced-apart regions or features or islands of the at least one functionalizable polymeric material are of a size ranging between being substantially 2-dimensional, namely being thin geometrical patterns, and 3-dimensional, wherein the regions or features outwardly extend as “pillars” or “pins”, with one end formed on the substrate (e.g., and through the perovskite film) and surrounded by the perovskite material of the perovskite film or layer (this end may be regarded as perturbing from the substrate through the perovskite layer) and the other end extending away from the substrate or material layers underlining the perovskite film or layer.

In some embodiments, the islands are 3D shaped regions.

A functional article of the invention is designed to form an integral part of a device such as a photovoltaic device, or a solar cell device, as described herein. However, in some embodiments, the article is designed to be a stand-alone article utilized for the manufacturing of a device of the invention or for any other purpose as known in the art.

In some embodiments of articles and devices of the invention, implementing a perovskite film having a plurality of islands of at least one polymerizable material, the islands, being shaped as pillars or pins, extend the surface of the perovskite film and penetrate or pin through one or more adjacent material layers, in e.g., a multilayered article or device.

Thus, the invention also provides a device comprising or implementing a perovskite film according to the invention.

In some embodiments, the device is a multilayered or stacked device, wherein the perovskite film is a topmost layer and wherein the polymeric regions extend substantially perpendicularly away from the perovskite layer or the multilayered or stacked device.

In some embodiments, a device implementing a perovskite film according to the invention is a photovoltaic device.

In some embodiments, a device implementing a perovskite film of the invention is a flexible solar cell device, optionally fabricated on a polymeric substrate. In some embodiments, the device may be utilized as a Building Integrated Photovoltaic device (BIPV), e.g., by retrofitting, namely placing the flexible semi-transparent solar cell onto existing windows (retrofitting), which may be flat or curved.

In some embodiments, a device of the invention comprises a plurality of electrically connected solar cells according to the invention.

As detailed herein, the polymeric spaced-apart regions or features formed in the perovskite layer or the device volume may be geometrically organized or shaped or their distribution and shape may be controllable to modulate (increase or decrease) one or more photo or electronic characteristic. Perpendicularly or angularly extending from any surface region of a substrate onto which a perovskite film is formed, permits control over or modulation of such properties. In some configurations, the polymeric regions configured to form transparent and functionalizable pillar features within a bulk of a multilayered structure, such that they protrude each and every layer of the multilayered structure, may be structured and formed to extend from any layer of the structure, not necessarily the substrate, and/or to extend the structure multilayered assembly to any distance, not necessarily from the substrate to the top most layer. Thus, selecting surface distribution, location, density, length and composition of each of the polymeric features, independently, may assist in increasing or decreasing or modulating or controlling photo and/or electronic characteristics of the structure.

Generally speaking, the distribution and shape of the polymeric regions or features may be varied to provide sufficient transparency therethrough; namely as means to increase transparency of the perovskite layer, perovskite structure or perovskite-based device. The composition of each of the polymeric regions or features, independently, and/or the overall size (surface coverage, length, diameter, etc) of each of the polymeric regions or features may be also tailored or modified to maximize transparency. In some embodiments, the surface area coverage (of each of the regions individually or the total surface coverage) by the polymeric material may vary according to a required transparency and overall efficiency of the cell.

In some embodiments, the polymeric regions or pillars are formed or printed on specific preselected regions of a substrate, or a substrate device, e.g., a solar cell device, thus providing a pattern which can serve a specific function or for aesthetic/artistic purposes.

In some embodiments, the polymeric material is selected according to its photo or electronic properties.

In some embodiments, the polymeric material is selected according to its optical properties such as transparency, refractive index, color and optionally further based on its ability to serve as a waveguide.

In some embodiments, the polymeric material is selected based on its ability to serve as a waveguide, based on, e.g., the polymer measured or known refractive index, transparency and optionally the polymer's other optical properties.

In some embodiments, the polymeric material may contain up- or down-converting materials or light scattering particles.

In some embodiments, the polymeric material is selected based on its suitability for a specific fabrication method.

The polymeric features, namely their composition, size, distribution, location etc, as detailed herein, and optionally further the selection of a perovskite material may improve transparency of the perovskite film. The improved transparency and properties of perovskite films according to the invention may be reflected in at least the film average visible transmittance (AVT) as well as in the film or device, i.e., photovoltaic device, ability to store and transfer energy (or voltage), namely in a device improved power conversion efficiency (PCE). As results provided herein indicate, an efficient semi-transparent perovskite film (when implemented as a solar cell) demonstrates 11.2% PCE with an AVT of at least 27%. Deposition of transparent contacts results in a PCE of 10.6% and slightly reduced AVT of 22%.

As known in the art and disclosed in the background of the invention, transparent or semitransparent perovskite-based devices demonstrate AVT values ranging from approximately 10%, and in some cases even lower, and 38% or so. A perovskite film having a transparency of between 18 and 22%, however, is considered sufficient for photovoltaic applications. Thus, an AVT of 27% or more, as measured for devices of the invention, is superior and highly applicable for a variety of uses.

The power conversion efficiency (PCE) of a perovskite film or a device implementing same relates to the proportion between the useful output of a device which converts energy (e.g., a photovoltaic device which converts the energy of light to electrical energy) and the input of such device (in energy terms). In other words, it reflects an energy input—energy of light—and energy output in terms of electrical power. PCE values measured for devices of the invention are clearly superior.

A photovoltaic device implementing a perovskite layer (or film) according to the invention is generally a stacked multilayered device; namely a device comprising a plurality of stacked films or layers, optionally formed on a substrate, wherein in some embodiments, at least one or each of the films or layers includes a patterned polymer/perovskite structure. The device may be structured as a mesoporous structure or as a planar heterostructure.

The invention further provides a photovoltaic cell device or a solar cell device or a device comprising a perovskite film and a plurality of spaced-apart pillars of at least one functionalizable polymeric material embedded within a plurality of material layers making up the device and extending the thickness of the device from a substrate of the device.

In some embodiments, the solar cell device is a mesoscopic device, wherein the perovskite absorber layer is associated with a mesoporous metal oxide framework for the purposes of increasing a light-receiving area of the photosensitive material and improving the efficiency of the device. Such a device may comprise a fluorine doped tin oxide or FTO electrode, an electron transport layer (which may be a dense layer), a mesoporous oxide layer, a perovskite layer, a hole transport layer and an electrode layer. In some embodiments, the device comprises an electron transport layer, a mesoporous oxide layer, a perovskite layer, a hole transport layer and optionally an electrode layer. In some embodiments, the device comprises a plurality of material layers which comprise an electron transport layer (ETL), a mesoporous oxide layer, a perovskite layer, and a hole transport layer (HTL).

TiO₂ may be used as a mesoporous framework material, which allows the perovskite nanocrystals to penetrate into pores thereof (e.g., by solution spin-coating) and forms an interconnected absorbing layer. In this structure, the TiO₂ layer may have a significant role in transporting electrons, blocking holes, or in inhibiting the recombination of the electron-hole pairs in the FTO conductive substrate. In addition to TiO₂, frame materials such as mesoporous metal oxides, such as ZnO, Al₂O₃ and ZrO₂ may also be used. The hole transport layer may be used to receive holes generated in the perovskite absorbing layer and transport them to the surface of the metal electrode. The hole transport material may be spiro-OMeTAD (2,2′,7,7′-tetrakis [N,N-di(4-methoxyphenyl)amino]-9,9′-spiro bifluorene).

ZnO may be used in place of TiO₂.

In some embodiments, the polymeric regions or pillars are printed on specific or predetermined regions of a solar cell, thus providing a pattern which can serve a specific function or for aesthetic/artistic purposes.

Unlike compact metal oxides, “mesoporous” metal oxides or layers thereof are materials or material layers containing pores with varying diameters (depending inter alia on the material and layer characteristics). Typically, the pores are voids formed in the layer or between particles in the layer, having diameters between 2 and 50 nm, allowing interpenetration of the perovskite material via the pores and through the layers. The mesoporous form may be ordered or disordered, yielding optionally crystalline mesoporous forms and amorphous mesoporous forms, respectively.

In some embodiments, a solar cell device according to the invention is configured as a planar heterojunction structure, wherein the main difference from the mesoscopic structure is that the planar structure removes the porous metal oxide layers. An interface is formed between the perovskite layer and the electron transport layer and the hole transport layer. Thus, the electron-hole pairs are separated rapidly and effectively by the electron transport layer and hole transport layer, respectively.

The device may alternatively be an inverted solar cell.

In some embodiments, the solar cell has a structure that is free of a hole transport material layer.

In some embodiments, the solar cell is a mesoporous, planar, inverted or hole-transport free device.

In some embodiments, the solar cell comprises a hole transport material layer, a perovskite layer and an electron transport material layer. The device may further comprise metal contact(s).

In some embodiments, the solar cell has the structure:

### Htl/Perovskite/ETL/Metal Contact

wherein
“HTL” is a hole transport material layer,
“Perovskite” is a perovskite material as defined and selected herein,
“ETL” is an electron transport material layer, and
“Metal contact” is a physical contact made of a metallic material selected from Au, Al, Cu, Ag and others.

As indicated, the metal contacts are formed on the ETL material layer.

In some embodiments, the HTL material layer comprises or consists an HTL material selected from NiOx, [2-(3,6-dimethoxy-9H-carbazol-9-yl)ethyl] phosphonic acid (MeO-2pacz), poly(3,4-ethylenedioxythiophene) polystyrene sulfonate (PDOT:PSS), poly[bis(4-phenyl)(2,4,6-trimethylphenyl)amine (PTAA) and others.

In some embodiments, the ETL material layer comprises or consists an ETL material that may be selected from [6,6]-phenyl-C₆₁-butyric acid methyl ester (PC61BM), ZnO, TiO₂ and others.

In some embodiments, the solar cell is configured with a topmost perovskite layer. In some embodiments, the solar cell is configured with the perovskite layer being a layer positioned between two other material layers.

The solar cell or photovoltaic device of the invention is fabricated as a multilayered device on a substrate, e.g., such as a glass substrate.

In some embodiments, the perovskite layer is formed on a mesoporous metal oxide layer such as a mesoporous TiO₂ layer or ZnO layer.

In some embodiments, the mesoporous metal oxide functions as a photoanode, deposited on top of a compact metal oxide, TiO₂ film/ZnO film. Thus, a device of the invention may comprise a functional multilayered structure comprising a substrate, a compact metal oxide layer and a mesoporous metal oxide layer, wherein the perovskite film of the invention is formed on the surface of the mesoporous metal oxide.

The TiO₂ or ZnO film may be formed by any method known in the art, including doctor blade and screen printing. Similarly, the HTL layer may be formed by such methods as spraying, doctor blade, inkjet printing and screen printing. Contact deposition, involving any one of inkjet printing, evaporation, screen printing, doctor blade, slot die coating, spraying and others may also be utilized for the deposition of any of the device layers or films.

In forming a film or a device of the invention, a substrate or a material layer (in case of a layered device) is first patterned with a polymeric material or a precursor thereof in a form of a polymerizable monomer, oligomer or pre-polymer thereof, to fabricate spaced-apart regions or features of a polymeric material. Once these spaced-apart regions are formed, a perovskite material is applied onto the patterned surface to substantially coat or cover surface regions which are not occupied by the spaced-apart features of the polymeric material. The perovskite film may be a standalone film or may be a layer or a film or a coat on a surface of a substrate or a layered device. When formed as a layered device such as a solar cell device, comprising a substrate, a compact metal oxide layer and a mesoporous metal oxide layer, the spaced-apart features of the polymeric material may be formed in such a way that the polymer may not substantially penetrate into the layered structure of the device. Combined with a film of the perovskite material that is formed once the polymeric regions are patterned, sufficient light penetration and efficient light propagation into the device are achievable.

In some embodiments, the polymeric islands, regions or pillars penetrate into the mesoporous layer, as defined herein.

The substrate onto which a device of the invention is formed (or on which a standalone perovskite film of the invention is formed) is any such solid material which may be flexible or rigid, thermally stable, which may be selected amongst glass substrates such as Corning Willow glass, plastic substrates such as polyethylene terephthalate (PET), polyimide (PI) and polyethylene naphthalate (PEN) and others. The substrate may be selected based on the final use of the device, the conditions for its preparation and other considerations as may be known in the art. The substrate may have no color or may be colored. Similarly, fabrication conditions may be adapted based on the substrate used.

As demonstrated, formation of the spaced-apart features increases the overall transparency of the device as compared with a perovskite-based device which does not include such regions. While the increase in transparency (e.g., measured as AVT values) may be dependent on a variety of factors relating to the structure and fabrication method thereof, its degree is uniquely high. In some embodiments, the transparency is increased from about 20% to about 25%. At times the transparency is increased up to 26%, 27%, 28%, 29%, 30%, 31%, 32%, 33%, 34%, 35%, 36%, 37%, 38%, 39% or 40%, wherein each separately constitutes an embodiment of the invention.

In some embodiments, the increase in transparency may be quantified and embodied in an average visible transmittance (AVT). As known in the art, AVT may refer to the weighted average transmittance of visible light in the solar spectrum that passes through the film or device. The AVT may be determined based on the photopic response of human eyes and solar energy flux for each respective wavelength. Alternatively, an AVT value may represent the average percentage of light transmitted by film or device, e.g., solar cell, in the visible wavelength (400-700 nm) based on the spectrally dependent response of the human eye.

AVT may be measured by various means known in the art.

Typically, a value of AVT for poorly transmitting films is below 10%. Semitransparent films or device and transparent films or device of the invention having between 12 or 15 and 35% and between 35 and 80%, respectively. Thus, semitransparent films or devices are characterized by an AVT value between 12 or 15 and 35%. Transparent films or device are characterized by an AVT value between 35 and 80%.

In some embodiments, films or devices of the invention exhibit AVT values between 12 and 80%, or between 12 and 70%, or between 12 and 60%, or between 12 and 50%, or between 12 and 40%, or between 12 and 30%, or between 12 and 20%, or between 20 and 70%, or between 20 and 60%, or between 20 and 50%, or between 20 and 60%, or between 20 and 50%, or between 20 and 40%, or between 20 and 30%, or between 12 and 70%.

In some embodiments, films or devices of the invention exhibit AVT values of 20, 21, 22, 23, 24, 25, 26, 27, 28, 29, 20, 31, 32, 33, 34, 35, 36, 37, 38, 39 or 40%.

Not to limit or reduce the transparency of the device or of the perovskite film, the electrically conductive metal contacts are positioned or configured to minimize their effect on the transparency. In some embodiments, a device of the invention comprises two electrically conductive contacts, a top and a bottom contact. At times, the bottom metal contact is a continuous contact, and the top metal contact is formed as a grid layout to enable an efficient penetration of light. The transparent electrical layer can be an oxide such as ITO. Alternatively, or additionally, the metal contact may be formed of a transparent material further allowing better light transmission through the device.

In some embodiments, the metal contact is or comprises gold. In some embodiments, the metal contact is composed of a thin gold film positioned between two layers of metal oxide, such as MoO₃.

In order to further control the transparency of the device, or to delimit effects of manufacturing and structural factors on the transparency and PCE measured for devices of the invention, the spaced-apart regions of the polymeric material may be formed by printing. A full control of region diameter, size, height, width and shape, a distance between the spaced-apart features and the overall patterning of the surface is possible by utilizing a printing device such as inkjet printer which printing nozzle can be configured and adapted for such patterning. Irrespective of the shape of the regions, their composition and their surface density and distribution, the distance or spacing between any two regions (in both X and Y directions) may be constant along the patterned surface or may be random. The term “spaced-apart” thus refers to a distance that defines a location of each island or region with respect to another or to a distance between the outermost surfaces of any two regions or features of the polymeric material, wherein said distance defines regions free of a polymeric material and which are occupied by a perovskite material. The spacing or the distance between any two regions may be as indicated herein. The height of the pillars can be controlled by the printing process and the composition of the printed materials. In some embodiments, the printing is performed by methods other than inkjet printing, such as screen printing.

In some embodiments, the distance or spacing between any two polymeric islands or regions (e.g., distance between boundaries of the regions) may be between 1 μm and 600 μm. In some embodiments, the distance is between 10 μm and 600 μm, between 50 μm and 600 μm, between 100 μm and 600 μm, between 150 μm and 600 μm, between 200 μm and 600 μm, between 250 μm and 600 μm, between 300 μm and 600 μm, between 350 μm and 600 μm, between 400 μm and 600 μm, between 450 μm and 600 μm, between 500 μm and 600 μm, between 550 μm and 600 μm, between 10 μm and 550 μm, between 10 μm and 500 μm, 10 μm and 450 μm, between 10 μm and 400 μm, between 10 μm and 350 μm, between 10 μm and 300 μm, between 10 μm and 250 μm, between 10 μm and 200 μm, between 10 μm and 150 μm, between 10 μm and 100 μm, between 10 μm and 50 μm, or between 10 μm and 25 μm.

Each of the spaced-apart islands or regions (pillars) may have its longest axis, and/or diameter in the micrometer scale. Generally speaking, the diameter of the regions or pillars is up to 1000 μm or between 25 and 1000 μm. In some embodiments, the diameter is between 25 and 900 μm or up to 800 or up to 700 or up to 600 or up to 500 μm. In some embodiments, the size or diameter is between 50 and 500 μm, 100 and 500 μm, between 150 and 500 μm, between 200 and 500 μm, between 250 and 500 μm, between 300 and 500 μm, between 350 and 500 μm, between 400 and 500 μm, between 450 and 500 μm, between 50 and 450 μm, between 50 and 400 μm, between 50 and 350 μm, between 50 and 300 μm, between 50 and 250 μm, between 50 and 200 μm, between 50 and 150 μm, between 50 and 100 μm, between 50 and 75 μm, between 25 and 450 μm, between 25 and 400 μm, between 25 and 350 μm, between 25 and 300 μm, between 25 and 250 μm, between 25 and 200 μm, between 25 and 150 μm, between 25 and 100 μm or between 25 and 75 μm.

Each or a portion of the spaced-apart islands or regions of at least one functionalizable polymeric material is fabricated to extend outwards from the perovskite layer, from the substrate or from any of the layers making up a multilayered structure of the invention, as defined herein. While it is believed that substantially all of the regions are formed as pillars, for the purpose of achieving maximum or effective transparency as well as PCE, it may be possible that only a portion of the regions may be of sufficient lengths or height. Generally speaking, the height of the polymeric pillars can be tailored. In some embodiments, the length or height of the polymeric pillars, measured from the surface of the perovskite layer, or from the substrate or from a layer of the multilayered structure from which the pillar extends, may be between about 50 nm and 1000 nm. In some embodiments, the pillar length is between about 100 nm and 1000 nm; between 150 nm and 1000 nm; between 200 nm and 1000 nm; between 250 nm and 1000 nm; between 300 nm and 1000 nm; between 350 nm and 1000 nm; between 400 nm and 1000 nm; between 450 nm and 1000 nm; between 500 nm and 1000 nm; between 550 nm and 1000 nm; between 600 nm and 1000 nm; between 650 nm and 1000 nm; between 700 nm and 1000 nm; between 750 nm and 1000 nm; between 800 nm and 1000 nm; between 850 nm and 1000 nm; between 900 nm and 1000 nm; or between 950 nm and 1000 nm. Alternatively, the pillar length is between about 100 nm and 950 nm; between 100 nm and 900 nm; between 100 nm and 850 nm; between 100 nm and 800 nm; between 100 nm and 750 nm; between 100 nm and 700 nm; between 100 nm and 650 nm; between 100 nm and 600 nm; between 100 nm and 550 nm; between 100 nm and 500 nm; between 100 nm and 450 nm; between 100 nm and 400 nm; between 100 nm and 350 nm; between 100 nm and 300 nm; between 100 nm and 250 nm; between 100 nm and 200 nm; between 100 nm and 150 nm; or between 100 nm and 120 nm. In some embodiments, the height of the polymeric materials may be in microns or tens of microns dimension, and if required they can be trimmed-off at any step of the overall cell fabrication process.

In some embodiments, each of the aforementioned lengths or heights is measured from the surface of the perovskite layer. In some embodiments, each of the aforementioned lengths or heights is measured from the surface of the substrate.

In some embodiments, each of the aforementioned lengths or heights is measured from the surface of the pillar base (from the surface point it extends from) to the topmost surface of the structure or device.

As noted herein, perovskite films and devices implementing same, according to the herein disclosed technology, are generally fabricated by first patterning a surface region of a substrate or a layered material with a polymeric material or a monomer, oligomer or pre-polymer thereof, to fabricate thereon spaced-apart regions of the polymeric material. Once these spaced-apart regions are formed, a perovskite material is applied onto the patterned surface to substantially coat or cover the surface regions which are not occupied by the spaced-apart regions of the polymeric material. As used herein, the spaced-apart regions are said to be of “at least one functionalizable polymeric material”, or simply of a “polymeric material”. The at least one polymeric material which forms the regions may be fabricated by in-situ polymerization of a polymer precursor or a polymerizable material such as a monomer, an oligomer, a prepolymer or any polymerizable material composition, under conditions permitting polymerization of the polymer precursor into a desired polymeric material. Alternatively, the polymeric regions may be formed by depositing a polymeric material (or patterning the surface with a polymeric material) under suitable conditions.

The polymeric material formed is said to be “functionalizable”. In other words, the polymeric material is selected amongst such polymeric materials or precursors thereof which may be functionalized by chemical modification, pre deposition, or in-situ, or by comprising (e.g., by admixing) a functionalized material that can endow the polymeric regions formed with additional mechanical, chemical, optical or structural properties. Whether functionalization is achieved by chemical modification of the polymer precursor or the polymerizable material or by a functionalized material, neither the modification nor the addition of the functionalized material interferes with the transparency and/or PCE of the manufactured perovskite film or device.

In a process for fabricating a film or a device of the invention, the process comprises forming spaced-apart islands or regions or pillar features of at least one functionalizable polymeric material on a surface region of a substrate and coating regions of the surface region not coated with the at least one functionalizable polymeric material with at least one perovskite material.

In some embodiments, forming the spaced-apart regions comprises depositing on a surface region (one or more or a plurality of such regions) a polymer precursor or a polymerizable material and causing said polymer precursor or polymerizable material to convert into the at least one functionalizable polymeric material.

In some embodiments, a polymer precursor is deposited, said precursor being optionally selected from monomers, oligomers or prepolymers of said polymeric material with proper additives that would enable tailoring the printing materials properties to the printing technology and to spreading on the substrate.

In some embodiments, a polymerizable material that can be converted into the polymeric material is deposited. In some embodiments, the printing compositions contain a solvent or a reactive diluent.

In some embodiments, the polymer precursor or the polymerizable material is deposited in combination or in presence or sequentially with at least one catalyst or polymerization initiator, e.g., a photoinitiator. In some embodiments, the polymer precursor or the polymerizable material is deposited in combination or in presence or sequentially with at least one catalyst or polymerization initiator and the deposited materials are irradiated or thermally treated to induce polymerization into the polymeric material. The polymerization can be based on a photopolymerization process, for which the composition from which the polymer is formed contain monomers/oligomers, photoinitiators and additive to enable control of the photopolymerization process, such as synergists and oxygen scavengers.

Thus, in a process of the invention, forming the spaced-apart regions comprises depositing a polymerizable formulation on the surface region (one or more or a plurality of such regions) and irradiating or thermally treating the deposited polymerizable formulation to convert into the at least one functionalizable polymeric material and obtain a patterned surface of spaced-apart polymeric regions, wherein the polymerizable formulation comprises a polymer precursor and/or a polymerizable material and a photoinitiator. For the purpose of the present invention, the “photoinitiator” may be any conventional photoinitiator or compositions of photoinitiators utilized in 2D and 3D printing (such as UV-curable inks), capable of causing polymerization when exposed to a light source producing light having a wavelength that activates the photoinitiator. Non-limiting examples of suitable photoinitiator include a single photoinitiator or several photoinitiators, or combination of such photoinitiators with dyes, photosensitizers, oxygen scavengers e.g., a dye/amine, a sensitizer/iodonium salt, a dye/borate salt, and others. Photopolymerization can be performed through a radical, cationic or any other mechanism.

In some embodiments, the refractive index of the polymeric material is selected so as to match the refractive index of the relevant layers of the cells, to provide maximal transparency.

In some embodiments, the polymeric material is a hybrid organic-inorganic material in which the refractive index can be tailored according to the proportion of the organic and inorganic content.

In some embodiments the polymeric material contains optical additives, e.g., dyes or particles enabling obtaining colored polymers or light scattering effect respectively.

In some embodiments, the pillars may be composed of different materials. For example, different dyes within the individual pillars may enable patterning of areas with different colors, thus imparting special patterning and visual effects to the fabricated solar cells. This may be achieved, for example, by inkjet printing of printing compositions from different printheads, in each the ink contains a different color. Deposition of the polymer precursor or the polymerizable material and the photoinitiator onto a surface region to pattern the surface with spaced-apart polymeric pillars may be achieved by any deposition means. In some embodiments, deposition comprises use of a patterning device. The patterning device may be a printer such as an inkjet printer, in which case deposition comprises or is by printing, e.g., inkjet printing.

Alternatively or additionally, deposition may involve any one or more of stereolithography (SLA), Polyjet, digital light processing (DLP), multi jet fusion (MJF) fused deposition modeling (FDM), screen printing and others.

In some embodiments, deposition may be achievable by printing in composition with one or more different deposition methods, e.g., spin coating, slot-die coating and others. In some embodiments, printing is achievable by inkjet printing in combination with a deposition method selected from spin coating, slot-die coating, stereolithography (SLA), Polyjet, digital light processing (DLP), multi jet fusion (MJF) fused deposition modeling (FDM), screen printing and others.

As noted herein, in a process for fabricating a film or a device of the invention, the patterned surface is coated with a perovskite material such that regions between the spaced-apart polymeric pillars are deposited with the perovskite material. Coating, depositing or treating with the perovskite material may comprise any coating technique, including for example spin coating.

In some embodiments, the surface onto which the polymeric regions and the perovskite layer are formed is a topmost surface of an electronic or a photo electronic device such as a solar-cell device. As demonstrated herein, the ink formulation which is usually composed of a polymer precursor or a (photo) polymerizable material and a photoinitiator is inkjet printed on top of a topmost layer of a device, where in some cases such topmost layer comprising a mesoporous TiO₂, and the printing is carried out in such a way that the diameter of the printed regions and the distances between them are fully controllable and can be pre-defined by the printing unit. Since the ink formulation in its pre-cured form is substantially liquid or semi-liquid, it has to be irradiated during the printing process so the polymer precursors, e.g., monomers of the polymerizable material are linked together to form a solid polymer. Such a polymer, according to the invention, is substantially transparent. In some embodiments, the polymeric material from which the spaced-apart polymeric regions are composed may be selected amongst acrylates and vinyl containing materials. In some embodiments, a photopolymerizable material which can be used is N-vinylcaprolactam.

In some embodiments, a photopolymerizable material which can be used is an acrylic monomer having various numbers of acrylic groups in the monomer, or oligomers such as urethan-acrylates. The specific material composition may be selected according to the chemical and physical properties of the resulting polymer, such as its adhesion to the substrate, durability and wetting properties. The photopolymerizable monomers and/or oligomers can have additional functional groups, such as in the case of epoxy acrylates, that can be further polymerized by other polymerization mechanism.

Suitable polymerizable materials can be found in h ex.com/en/, or in Bagheri et al., ACS Appl. Polym. Mater. 2019, 1, 4, 593-611, for utilization in 3D printing.

In some embodiments, the ink formulation is irradiated with a light source such as a UV light source, a LED light source, an IR light source or a laser light source.

A device according to the invention may be formed with any perovskite material known in the art. Solar cells or photovoltaic devices formed according to the invention exhibit a relatively high transparency and high-power conversion efficiency. The composition of the perovskite can also enable obtaining solar cells with controlled variety of colors.

Thus, a perovskite material used in accordance with the invention comprises or consists one or more perovskite species, encompassing any perovskite structure known in the art. The perovskite material is typically characterized by the structural motif AMX₃, having a three-dimensional network of corner-sharing MX₆ octahedra, wherein M is a metal cation that may adopt an octahedral coordination of the X anions, and wherein A is a cation typically situated in the 12-fold coordinated holes between the MX₆ octahedra.

In some embodiments, A and M are metal cations, i.e., the perovskite material is a metal oxide perovskite material. In other embodiments, A is an organic cation and M is a metal cation, i.e., the perovskite material is an organic-inorganic perovskite material.

In some embodiments, the perovskite material is of the formula:
AMX₃ or
AMX₄ or
A₂MX₄ or
A₃MX₅ or
A₂A′MX₅ or
AMX₃₋ₙX′ₙ,
wherein, in each of the above formulae, independently:
each A and A′ are independently selected from organic cations, metal cations and any combination of such cations;
M is a metal cation or any combination of metal cations;
each X and X are independently selected from anions and any combination of anions; and
n is between 0 to 3.

The metal cations may be selected from metal element of Groups IIIB, IVB, VB, VIB, VIIB, VIIIB, IB, IIB, IIIA, IVA and VA of block d of the Periodic Table of the Elements.

In some embodiments, the metal cation is Li or Mg or Na or K or Rb or Cs or Be or Ca or Sr or Ba, Sc or Ti or V or Cr or Fe or Ni or Cu or Zn or Y or La or Zr or Nb or Tc or Ru or Mo or Rh or W or Au or Pt or Pd or Ag or Co or Cd or Hf or Ta or Re or Os or Ir or Hg or B or Al or Ga or In or Tl or C or Si or Ge or Sn or Pb or P or As or Sb or Bi or O or S or Se or Te or Po or any combination thereof.

In some embodiments, the metal cation is a transition metal selected from Groups IIIB, IVB, VB, VIB, VIIB, VIIIB, IB and IIB of block d the Periodic Table. In some embodiments, the transition metal is a metal selected from Sc, Ti, V, Cr, Mn, Fe, Ni, Cu, Zn, Y, Zr, Nb, Tc, Ru, Mo, Rh, W, Au, Pt, Pd, Ag, Mn, Co, Cd, Hf, Ta, Re, Os, Ir and Hg or any combination thereof.

In some embodiments, the metal cation is a post-transition metal selected from Group IIIA, IVA and VA. In some embodiments, the metal cation is Al or Ga or In or Tl or Sn or Pb or Bi or any combination thereof.

In some embodiments, the metal cation is a semi-metal selected from Group IIIA, IVA, VA and VIA. In some embodiments, the metal cation is B or Si or Ge or As or Sb or Po or any combination thereof.

In some embodiments, the metal cation is an alkali metal selected from Group IA. In some embodiments, the metal cation is an alkali metal Li or Mg or Na or K or Rb or Cs.

In some embodiments, the metal cation is an alkaline earth metal selected from Group IIA. In some embodiments, the metal cation is Be or Ca or Sr or Ba.

In some embodiments, the metal cation is a lanthanide element such as Ce or Pr or Gd or Eu or Tb or Dy or Er or Tm or Nd or Yb or any combination thereof.

In some embodiments, the metal cation is an actinides element such as Ac or Th or Pa or U or Np or Pu or Am or Cm or Bk or Cf or Es or Fm or Md or No or Lr or any combination thereof.

In some embodiments, the metal cation is a divalent metal cation. Non-limiting examples of divalent metals include Cu⁺², Ni⁺², Co⁺², Fe⁺², Mn⁺², Cr⁺², Pd⁺², Cd⁺², Ge⁺², Sn⁺², Pb⁺², Eu⁺² and Yb⁺².

In some embodiments, the metal cation is a trivalent metal cation. Non-limiting examples of trivalent metals include Bi⁺³ and Sb⁺³.

In some embodiments, the metal cation is Pb⁺².

The organic cations comprise at least one organic moiety (containing one or more carbon chain or hydrocarbon chain or one or more organic group). The organic moiety may be selected from substituted or unsubstituted alkyl, substituted or unsubstituted alkenyl, substituted or unsubstituted alkynyl, substituted or unsubstituted cycloalkyl, substituted or unsubstituted cycloalkenyl, substituted or unsubstituted cycloalkynyl, substituted or unsubstituted aryl, substituted or unsubstituted heteroaryl, substituted or unsubstituted heterocyclyl, substituted or unsubstituted —NR₁R₂, substituted or unsubstituted —OR₃, substituted or unsubstituted —SR₄, substituted or unsubstituted —S(O)R₅, substituted or unsubstituted alkylene-COOH, and substituted or unsubstituted ester.

The variable group denoted by “R”, in any one of the generic descriptions e.g., —NR₁R₂, —OR₃, —SR₄, —S(O)R₅, refers to one or more group selected from hydrogen, alkyl, alkenyl, alkynyl, cycloalkyl, cycloalkenyl, cycloalkynyl, aryl, heteroaryl, heterocyclyl, halogen, alkylene-COOH, ester, —OH, —SH, and —NH, as defined herein or any combination thereof. In some embodiments, the number of R groups may be 0 or 1 or 2 or 3 or 4 or 5 or 6 or 7 or 8 or 9 or 20. As used herein, the group R refers generically to any specific R used herein, unless a specific definition is provided; in other words, the aforementioned definition refers to any of the R groups, e.g., R′, R″, R′″, R″″, R₂, R₃, R₄, R₅, R₆, R₇, R₈, etc, unless otherwise specifically noted.

In some embodiments, the at least one anion is an organic anion or an inorganic anion as known in the art. In some embodiments, the anion is a halide ion (F, Br, Cl, or I).

In some embodiments, the perovskite material is a single species of a perovskite material. In other embodiments, the perovskite material is a combination of two or more (several) different species of different perovskite materials. In some embodiments, the number of different species of different perovskite materials may be 2 or 3 or 4 or 5 or 6 or 7 or 8 or 9 or 10 different perovskite species.

In some embodiments, the perovskite material is selected from:
Cs₁₋ₓFAₓPb(I_{1-y}Br_{y})₃, wherein each of x and y, independently, may be between 0 and 1; in some embodiments, each of x an y, independently, may be between 0 and 1, but is not zero;
Cs_{0.2}FA_{0.8}Pb(I_{0.6}Br_{0.4})₃;
Cs_{0.15}FA_{0.75}MA_{0.10}PbI₂Br;
Cs_{0.15}FA_{0.85}PbI₂Br;
FAₓMAₓ₋₁Y, wherein Y is the perovskite species and wherein 0<=x<=1;
FA_{0.85}MA_{0.15}PbI₃;
FA_{0.85}MA_{0.15}PbI₂Br;
FA_{0.85}MA_{0.15}PbIBr₂;
and others, wherein FA is formamidine and MA is methylamine.

In some embodiments, the perovskite material is provided as a multilayered structure of layered perovskite materials, wherein each layer is of the same or different perovskite material.

In some embodiments, where the perovskite materials in the different layers are different, the difference may be in the species of a perovskite material, a mixture of several different species of perovskite materials, the ratio between the different perovskite materials, etc. In some embodiments, each layer in a perovskite multilayer is made of a different combination or the same combination but with different ratios of perovskite materials.

In some embodiments, where the perovskite material is in a form of a multilayered perovskite material, each of the perovskite layers in the multilayer may be of the same perovskite material or of different perovskite materials. In some embodiments, the multilayer perovskite comprises 2 or 3 or 4 or 5 or 6 or 7 or 8 or 9 or 10 perovskite layers.

In some embodiments, the perovskite material comprises 2 or 3 or 4 or 5 or 6 or 7 or 8 or 9 or 10 different perovskite materials, each being selected and defined as above.

In some embodiments, the perovskite material comprises two perovskite materials at a ratio of 1:1 or 1:2 or 1:3 or 1:4 or 1:5 or 1:6 or 1:7 or 1:8 or 1:9 or 1:10 or 1:100 or 1:200 or 1:300 or 1:400 or 1:500.

In some embodiments, the perovskite material is of the structure APbI₃, wherein A is an amine (or corresponding ammonium) or at least one amine (or corresponding ammonium) compound such that where the number of amines is greater than 1, the ratio amine(s):Pb is 1.

In some embodiments, the at least one amine (or corresponding ammonium) is selected from aromatic and aliphatic amines. In some embodiments, the amine is formamidine (FA) and/or methylamine (MA). In some embodiments, the amine is a combination of formamidine and methylamine.

In some embodiments, the perovskite is selected from FAₓMAₓ₋₁Y, wherein Y is the perovskite species and wherein 0<=x<=1, such systems may be FA_{0.85}MA_{0.15}PbI₃, FA_{0.85}MA_{0.15}PbI₂Br, FA_{0.85}MA_{0.15}PbIBr₂, and others. Additional perovskites may be Cs_{0.15}FA_{0.75}MA_{0.10}PbI₂Br, Cs_{0.15}FA_{0.85}PbI₂Br and others.

In a particular embodiment, the perovskite material is Cs_{0.2}FA_{0.8}Pb(I_{0.6}Br_{0.4})₃.

In some embodiments, the perovskite layer comprises or consists an inorganic perovskite material. In some embodiments, the perovskite layer comprises or consists an inorganic-organic perovskite material.

The perovskite material can be formed by various wet-deposition methods, including but not limited to inkjet printing, screen printing, spray coating, dip-coating and spin-coating. In some embodiments, the layer of the perovskite is composed of different perovskite types within the same layer, thus enabling patterning with different colors, resulting in semi-transparent solar cells with different visual patterns.

The invention further provides a photovoltaic cell device comprising a perovskite film of a material selected from Cs_{0.2}FA_{0.8}Pb(I_{0.6}Br_{0.4})₃; Cs_{0.15}FA_{0.75}MA_{0.10}PbI₂Br; Cs_{0.15}FA_{0.85}PbI₂Br; FA_{0.85}MA_{0.15}PbI₃; FA_{0.85}MA_{0.15}PbI₂Br; or FA_{0.85}MA_{0.15}PbIBr₂; wherein FA is formamidine and MA is methylamine; and a plurality of spaced-apart pillars of at least one functionalizable polymeric material embedded within a plurality of material layers and extending the thickness of the device from a substrate of the device, wherein the material layers comprise an electron transport layer (ETL), a mesoporous oxide layer, a perovskite layer, and a hole transport layer (HTL).

In some embodiments, the device has the structure HTL/perovskite/ETL/metal contact, wherein “HTL” is a hole transport material layer, “Perovskite” is a perovskite material, “ETL” is an electron transport material layer, and “Metal contact” is a physical contact made of a metallic material.

### BRIEF DESCRIPTION OF THE DRAWINGS

In order to better understand the subject matter that is disclosed herein and to exemplify how it may be carried out in practice, embodiments will now be described, by way of non-limiting examples only, with reference to the accompanying drawings, in which:

FIG. 1 is a schematic illustration of the fabrication of semi-transparent perovskite-based solar cell according to some embodiments of the invention.

FIGS. 2A-2D show various illustrations, where FIG. 2A is SEM image of printed NVC-ink pattern on mesoporous TiO₂. Inset-magnification of a specific area that shows the ink columns. FIG. 2B is a photograph of the semi-transparent solar cell before the Au contact deposition. Inset-optical microscope of the perovskite deposited on the ink. FIG. 2C shows X-ray diffraction pattern obtained for the TiO₂/NVC-ink/perovskite substrate. FIG. 2D is the transmittance measurements of TiO₂/NVC-ink/Perovskite which provide 35% of transmittance and TiO₂/Perovskite which provide 23% of transmittance.

FIG. 3 shows a scanning-TEM (STEM) cross-section image of the semitransparent device. The individual color mapping shows the corresponding elements of the solar cell structure. The NVC-ink is penetrating the mesopores TiO₂ which increase the thickness of the mesoporous TiO₂ in the pillar region as can be seen from the HR-TEM cross section.

FIGS. 4A-4D shows various images, where FIG. 4A is Scanning-TEM (STEM) cross-section image of the device, where collective color mapping shows the bright spots corresponds to the Cs-richness. FIGS. 4B-4D are the high-resolution lattice scale images obtained in the Cs rich, interface of Cs-rich and Cs-deficient, and Cs-deficient areas respectively (the corresponding electron diffractograms are given in insets).

FIGS. 5A-5F provide PV parameters of the NVC-ink PSCs with ˜25% AVT. FIG. 5A shows a graph of short-circuit current density J_{sc}. FIG. 5B shows a graph of open-circuit voltage V_{oc}. FIG. 5C is a graph of the Fill-factor FF. FIG. 5D is a graph of power conversion efficiency (PCE). FIG. 5E is JV curve of champion NVC-ink device. FIG. 5F is EQE spectra of the champion NVC-ink device.

FIGS. 6A-6D provide various graphs where FIG. 6A provides graph of charge extraction measurement of NVC-ink and perovskite-grid semi-transparent devices. FIG. 6B is IMPS spectra of the NVC-ink and grid semi-transparent devices. FIG. 6C is a current-voltage curve of NVC-ink solar cell including transparent contact; Inset: image of the champion NVC-ink device including the transparent top MoO₃/Au (10 nm)/MoO₃ contact. FIG. 6D is a graph of the corresponding AVT and PCE values measured for the NVC-ink devices versus the overall area of the printed polymer column like structures.

FIGS. 7A-7B provides a schematic illustration of NVC-ink device. FIG. 7A illustrates a schematic the cross-sectional view of NVC ink-device. FIG. 7B is a 3-dimensional view of the perovskite grid-device.

FIG. 8 is a schematic representation of the number of NVC-ink spots present within the perovskite area of 1 mm².

FIG. 9 presents a graph of corresponding AVT and J_{sc} values measured for the NVC-ink devices versus the overall area of the printed polymer column like structures.

FIGS. 10A-D shows a rigid solar cell having NVC-ink pillars and a perovskite (Cs_{0.2}FA_{0.8}Pb(I_{0.6}Br_{0.4})₃) film printed by an ink-jet printer, (FIG. 10A) the schematic illustrates the device structure, (FIG. 10B) the optical photograph of the rigid semitransparent solar cell with the AVT of 30%, (FIG. 10C) the IV curve obtained for the device (measured under 1 SUN irradiation), and (FIG. 10D) the transmittance curve of the device.

FIGS. 11A-D shows a flexible solar cell whereas the NVC-ink pillars and the perovskite (Cs_{0.2}FA_{0.8}Pb(I_{0.6}Br_{0.4})₃) is printed by the ink-jet printer, (FIG. 11A) the schematic illustrates the device structure, (FIG. 11B) the optical photograph of the flexible semitransparent solar cell with the AVT of 32%, (FIG. 11C) the IV curve obtained for the device (measured under 1 SUN irradiation), and (FIG. 11D) the PCE is measured for the device versus the number of its bending cycles.

### DETAILED DESCRIPTION OF EMBODIMENTS

Descriptions of embodiments of the invention in the present application are provided by way of examples and are not intended to limit the scope of the invention. The described embodiments comprise different features, not all of which are required in all embodiments of the invention. Some embodiments utilize only some of the features or possible combinations of the features. Variations of embodiments of the invention that are described, and embodiments of the invention comprising different combinations of features noted in the described embodiments, will occur to persons of the art.

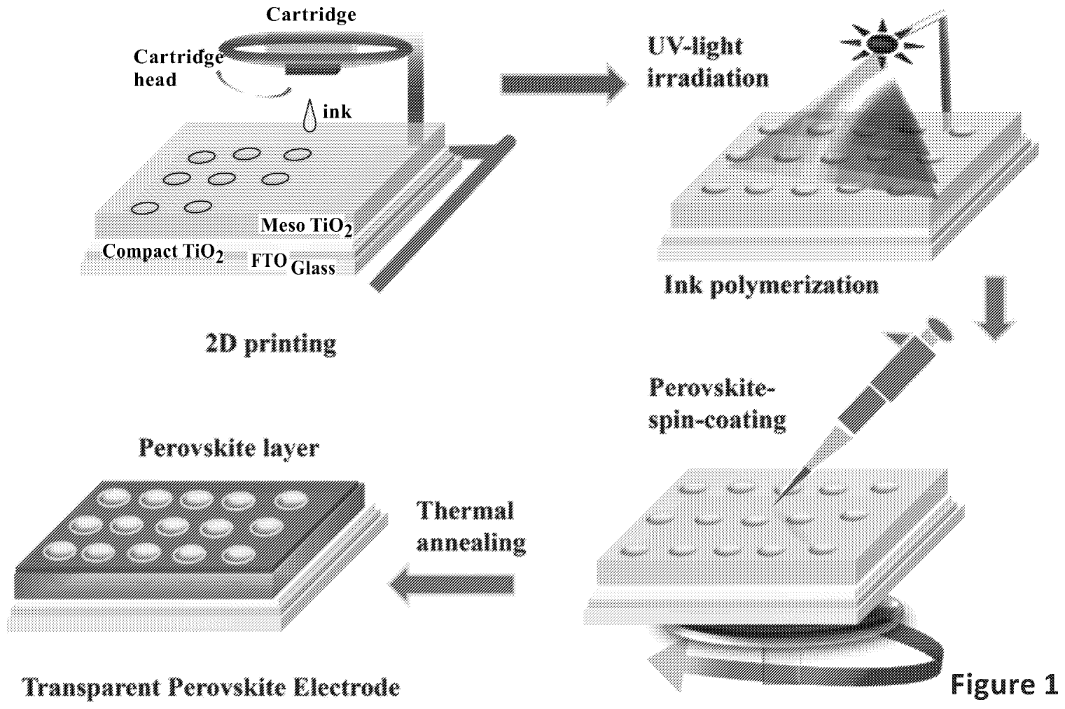

Presented herein is a novel and unique structure of a transparent or a semi-transparent perovskite solar cell. The main idea is based on printing islands of transparent column like structures or pillars, while the ink does not damage the photoanode and the perovskite. FIG. 1 schematically presents the process for the fabrication of semi-transparent perovskite cells. Basically, in some embodiments, the photoanode is a mesoporous TiO₂ layer, deposited on top of a compact TiO₂ film, while the substrate is FTO glass. The ink, which is composed of photopolymerizable material, such as N-Vinylcaprolactam and photoinitiator (NVC-ink), is inkjet printed on top of the mesoporous TiO₂ at specific locations and controlled distance. Upon irradiation by UV-light for short time, the monomers convert into a solid polymer, in the form of pillars or column like structures. The ink polymerization should be sufficiently fast, in order to prevent its penetration into the mesoporous TiO₂. Following the ink printing, a solution of perovskite (e.g., Cs_{0.2}FA_{0.8}Pb(I_{0.6}Br_{0.4})₃) is spin-coated on top of the device, and spread to the sides of the pillars, which results in the transparency of the film.

It should be noted that since the NVC-Ink is deposited by inkjet printing, the column like structures diameter and the spacings between the pillars can be fully digitally controlled by the printing file design and the nozzle diameter of the printer's cartridge.

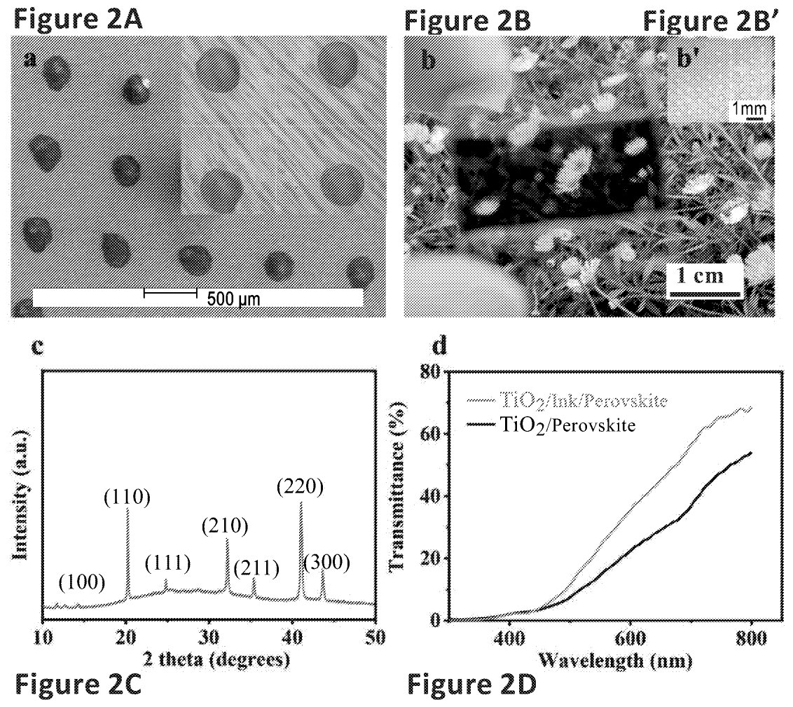

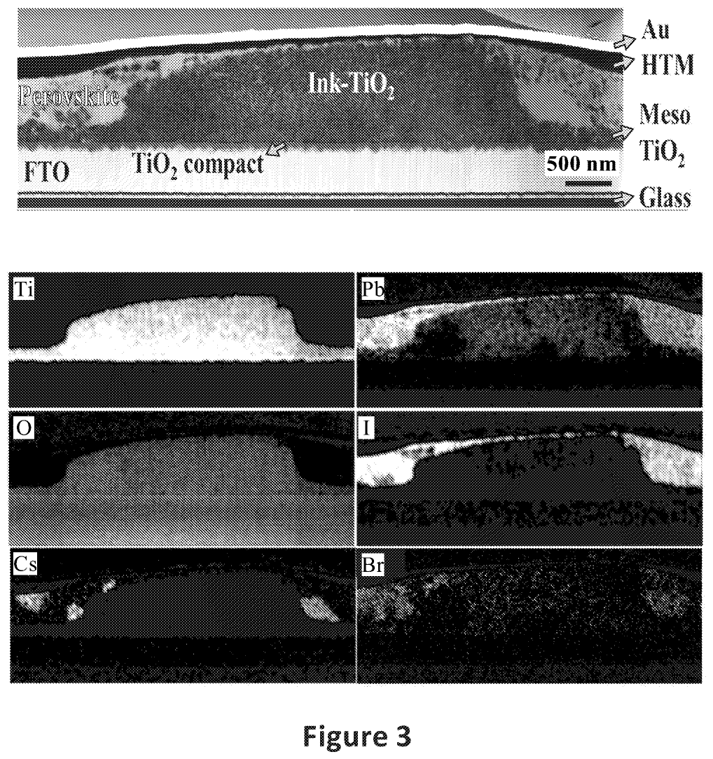

FIG. 2A shows a top view scanning electron microscope (SEM) image of the printed pillars on top of mesoporous TiO₂. The polymer ink-pattern is uniformly deposited with a diameter of ˜300 μm and distributed evenly on the mesoporous TiO₂ with a distance of ˜400 μm in both X and Y directions. The inset of FIG. 2A shows a magnification of the printed and polymerized ink (the ink height is ˜600 nm based on the High-resolution transmission electron microscopy (HR-TEM) as shown in FIG. 3). An image of the semi-transparent device without the metal contact can be seen in FIG. 2B, in which the perovskite film looks uniformly spread on the surface where the ink pattern cannot be recognized. Moreover, it appears from the cross-section image (FIG. 3), that the perovskite film is present both in the spacings between the pillars, and also coating the top of them by a thin film. The X-ray diffraction (XRD) pattern of the perovskite deposited on the ink printed TiO₂ electrode is shown in FIG. 2C. The diffraction patterns indicate inter planar distances of 7.55, 7, 6.21, 4.4, 3.58, 2.78, 2.53, 2.2, 2.1 Å which are corresponding to the crystallographic planes (100), (110), (111), (210), (211), (220), and (300), based on the inorganic crystal structure database (ICSD #243598) presented in Ali, A. et al. Machine Learning Accelerated Recovery of the Cubic Structure in Mixed-Cation Perovskite Thin Films. Chem. Mater. 32, 2998-3006 (2020), and Tan, W., Bowring, A. R., Meng, A. C., Mcgehee, M. D. & Mcintyre, P. C. Thermal Stability of Mixed Cation Metal Halide Perovskites in Air. ACS Appl. Mater. Interfaces 10, 5485-5491 (2018), which are both incorporated herein by reference.

A cubic crystal structure that belongs to Pm-3m space group is assigned for the thin perovskite layer.

FIG. 2D shows the transmittance of the TiO₂/NVC-Ink/Perovskite structure and of the TiO₂/Perovskite structures without printed ink. For perovskite film made from 0.6M solution the average visible transmittance (AVT, calculated between the wavelength 400-800 nm) is 23%. This transparency increased to 35% for NVC-ink structure, resulting from the voids which allow to a part of the visible light to pass through the perovskite layer.

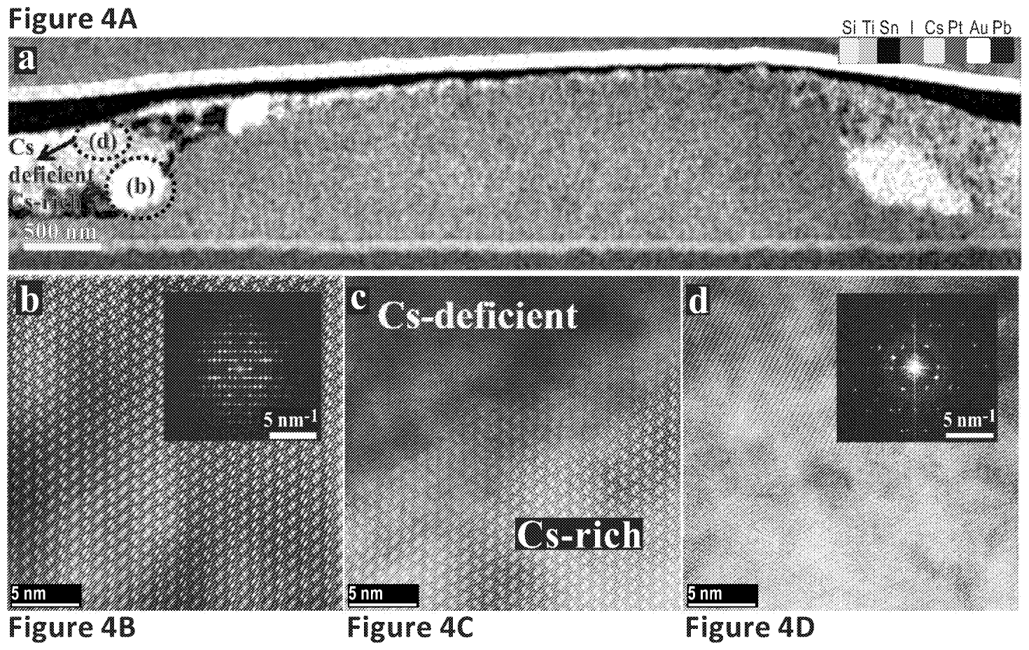

A focused ion beam (FIB) was used to get a cross-section of the solar cell and to analyze its structure and elemental chemical composition by HR-TEM (FIG. 3). The structure of the solar cell shows a compact TiO₂, mesoporous TiO₂, NVC-ink-TiO₂ composite, perovskite, HTM, and Au top contact. Interestingly, following the printing, the monomer NVC-ink spreads into the mesoporous TiO₂, which formed TiO₂-NVC ink composite. During polymerization of the ink, a composite of ink-TiO₂ is formed with a height of 600 nm compared to 200 nm of the meso-TiO₂ layer alone. Since the mesopores of the TiO₂ are filled by the NVC-ink, the perovskite cannot penetrate inside the pores in these places (as can be seen in FIG. 3 in the case of the elements Pb and Ti) which leads to the film transparency. On the other hand, the Pb, Cs, Br and I are observed clearly only at the perovskite areas and not inside the mesoporous TiO₂. Interestingly, the Cs seems to accumulate at specific grains inside the perovskite layer and not distributed homogeneously in the mixed cation perovskite. To verify this observation, there was performed a STEM imaging of cross-sections the specific areas in the cell (marked in FIG. 4A).

As seen in FIG. 4B, the Cs-rich area is composed of CsPbI₃ crystalline structure (ICSD #250744 in Table 2 with the corresponding h k 1 lattice parameters), whereas the Cs-deficient region (FIG. 4D) the crystal planes match the organic-inorganic hybrid perovskite structure [(CH₃)(NH₃)₂Pb(BrI)₃, PDF #01-085-6374]. FIG. 4C shows the transition from the Cs-rich to Cs-deficient regions.

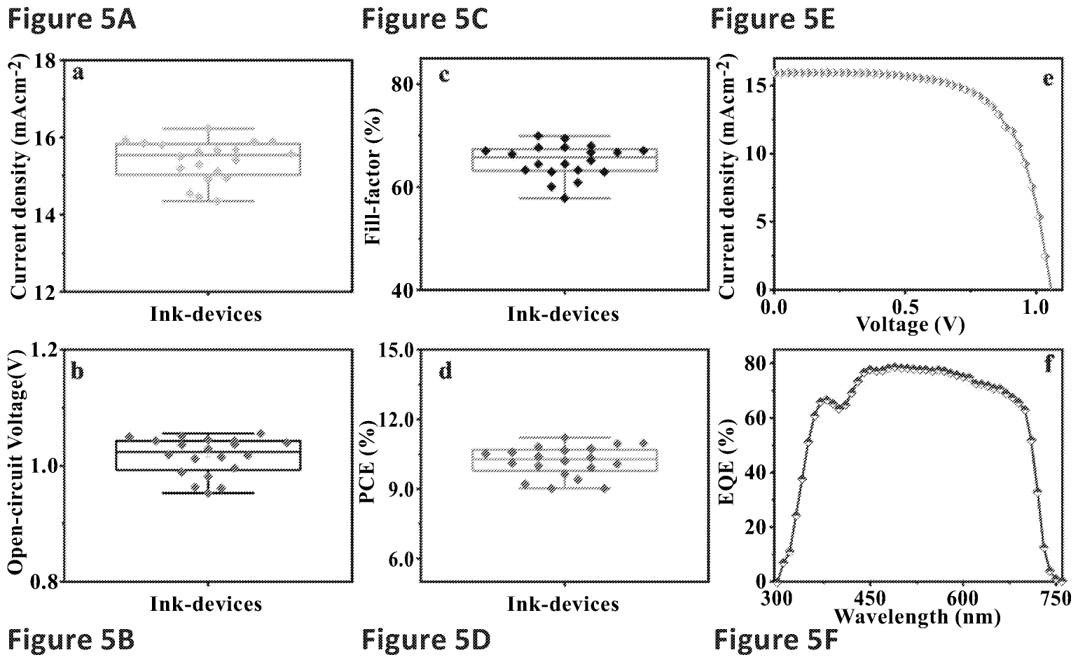

The photovoltaic parameters for the semi-transparent NVC-ink PSCs can be observed in Table 1 below and FIGS. 5A-D.

TABLE 1
The average PCE parameters obtained for twenty solar cells
and for the champion device with the configuration
FTO/TiO₂/NVC-ink/Perovskite/HTM/Au (active area is 0.088
cm²), under 1 Sun illumination. The transmittance is measured
before the deposition of the gold contact.

| V_{OC} (V) | J_{SC} (mAcm⁻²) | FF (%) | PCE (%) | AVT (%) |
|---|---|---|---|---|
| 1.02 +/− 0.06 | 15.4 +/− 1.05 | 65.1 +/− 7.3 | 10.2 +/− 1.0 | 26 +/− 2 |
| (1.06) | (15.9) | (66.7) | (11.2) | (27) |

TABLE 2
The miller indices obtained from the selected area electron
diffraction (SAED) patterns, during the HR-TEM measurement.

| | 2d-spacing (Å) | H | k | l |
|---|---|---|---|---|
| Cs-rich | 9.04 | 1 | 0 | 1 |
| | 5.25 | 2 | 0 | 0 |
| | 9.1 | 1 | 0 | −1 |
| | 8.97 | 0 | 0 | −2 |
| Cs-deficient | 2.0 | 3 | 0 | 0 |
| | 1.329 | 3 | 3 | 2 |
| | 0.99 | 5 | 3 | 2 |
| | 2.1 | 2 | 2 | 0 |

A narrow distribution of the PV parameters is shown for 20 cells (FIGS. 5A-D). An average power conversion efficiency (PCE) of 10.2% with 26% average transparency (AVT) shows that these semi-transparent solar cells can achieve a relatively high efficiency compared to other semi-transparent perovskite solar cells, such as that which is described in Jung, J. W., Chueh, C. & Jen, A. K. High-Performance Semitransparent Perovskite Solar Cells with 10% Power Conversion Efficiency and 25% Average Visible Transmittance Based on Transparent CuSCN as the Hole-Transporting Material. Adv. Energy Mater. 5, 1500486 (1-7) (2015) and in Ram, O. et al. Coloring Semitransparent Perovskite Solar Cells via Dielectric Mirrors. ACS Nano 10, 5104-5112 (2016).

Importantly, the AVT was measured before the Au contact deposition. One of the interesting parameters is the open-circuit voltage (V_{OC}) of these cells, and even though the ink height is expected to cause some recombination centers, due to the possibility of direct contact with the HTM layer, the V_{oc} is relatively high, with an average of 1.02V. The reason for that is mainly due to the thin overlayer of perovskite on top of the ink-TiO₂, as shown in FIG. 3. This thin perovskite layer prevents a direct contact between the HTM and the TiO₂. In an example of the herein invention, a champion device demonstrated V_{oc} of 1.06V, J_{SC} of 15.9 mA/cm², Fill Factor of 66.7% resulting in a PCE of 11.2% and AVT of 27% (without top contact).

Both the JV and the external quantum efficiency (EQE) curves measured for the champion cell are shown in FIGS. 5E-F. The EQE curve follows a similar trend of the absorption of mixed cation mixed halide Cs_{0.2}FA_{0.8}PbI_{0.6}Br_{0.4} perovskite. The small hump in the EQE spectra around 400 nm, can be associated with the insufficient absorption of the TiO₂ due to the ink penetration. The integrated J_{SC} obtained from the EQE is 15.8 mAcm⁻² which is in very good agreement with the J_{sc} measured by the solar simulator, 15.9 mAcm⁻², thus supports the reliability of the PV measurement.

In order to better understand the device performance mechanism, charge extraction (CE) and intensity-modulated photocurrent spectroscopy (IMPS) measurements were performed. Herein is the comparison of results obtained for the current NVC-ink semi-transparent devices to a previous reported technology of the inventors which includes semi-transparent technology of mesh assisted perovskite grid structure, which is described in Rahmany, S., Layani, M., Magdassi, S. & Etgar, L. Fully functional semi-transparent perovskite solar cell fabricated in ambient air. Sustain. Energy Fuels 1, 2120 2127 (2017) and which is incorporated herein by reference.

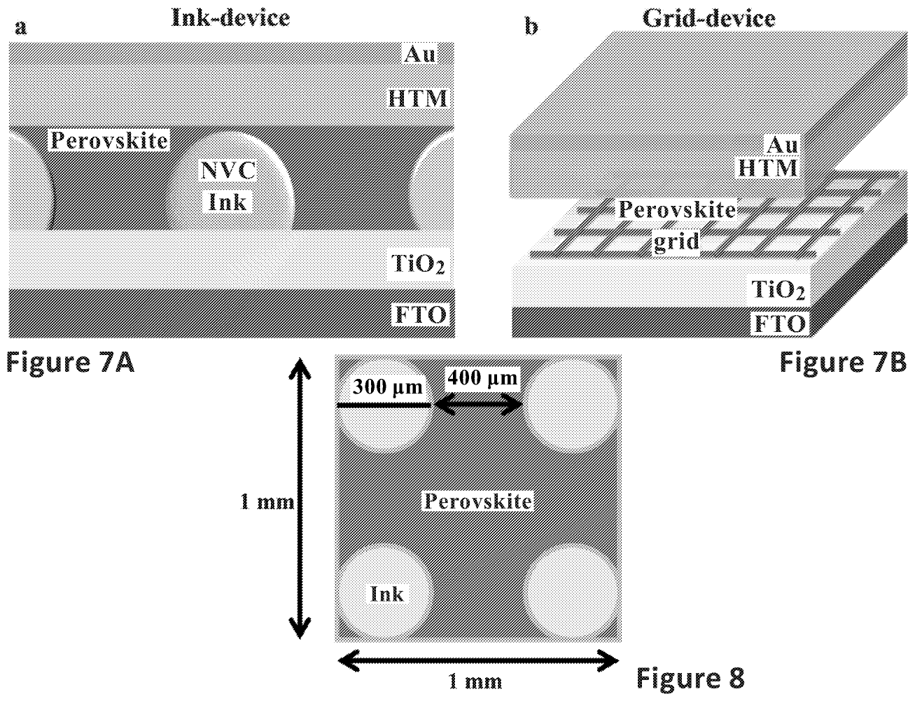

A schematic illustration of the semi-transparent grid perovskite solar cells can be found in FIG. 7B. Although the idea behind both structures is to improve the optical transmittance for the PSCs, the structural design is very different. In the case of perovskite grid structure, the perovskite is deposited on top of the photoanode using a directed assembly process based on using a mesh which creates a perovskite grid, on top of the mesoporous TiO₂ electrode. As a result, empty spaces are formed between the perovskite grid lines, thus providing the transparency on one hand, but on the other hand these are recombination centres in the device. In the NVC-ink devices, the optical transparency is attributed to the transparent voids which are created by the 300 to 400 μm column like structures present on the mesoporous TiO₂. It is important to note that this polymer is stable and does not react with the perovskite.

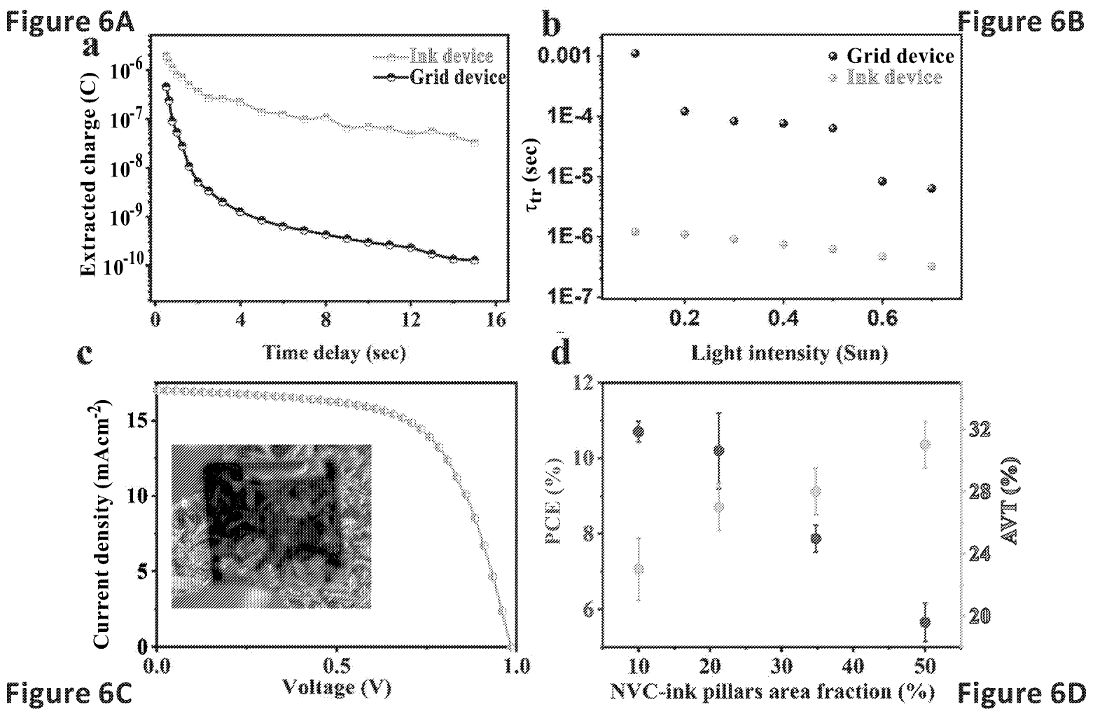

Moreover, the perovskite which coats the columns provides an over layer (FIG. 3) which prevent recombination between the HTM and the perovskite. CE measurements were used previously for several device structures, whereby this method the device is illuminated for 5 s under open-circuit conditions and then short-circuiting the cell and leaving it in the dark for a certain period of time (i.e., delay period), before closing the circuit and extracting the remaining charges. FIG. 6A shows the CE for the two different semi-transparent perovskite solar cell structures. The NVC-ink devices show a higher number of charges left at a certain delay time compared to the grid devices. For example, for NVC-ink devices, the extracted charge is 1.96×10⁻⁶ C after a delay time of 0.5 sec, and it decreases to 3.27×10⁻⁸ C for 15 sec delay time. However, for the perovskite grid devices, the extracted charge is 4.54×10⁻⁷ C after a delay time of 0.5 sec, which eventually decreases to 1.29×10⁻¹⁰ C after 15 sec. It can be concluded that the recombination in case of the NVC-ink device is lower than the recombination in the grid perovskite device. This observation is further supported by the IMPS measurements, which provides the electron transport time. FIG. 6B shows the electron transport time as a function of the light intensity for the NVC-ink devices and the grid devices. Clearly, transport is more efficient in the case of the NVC-ink devices. The reason for that lies in the perovskite overlayer which coats the column like structures, thus enabling a much more efficient transport of charges through the device, in contrast to the grid-based devices which have direct contact of the HTM and the mesoporous TiO₂. To summarize, these measurements show that the newly developed semi-transparent devices are efficient in preventing the shunt paths and charge recombination.

In the next step a transparent contact was deposited on top of the NVC-ink perovskite cells to create a fully semi-transparent perovskite solar cell. The transparent contact is composed of a thin gold film sandwiched between two layers of a metal oxide (i.e., MoO₃). The difference in the dielectric constant of the metal oxide and the gold provides the required transparency while the gold thickness affects the conductivity but also influence the transparency. Two different gold thicknesses were studied, 10 nm and 20 nm. Table 3 summarizes the average and the best PV parameters of the fully semi-transparent devices.

TABLE 3
The average PCE parameters obtained for ten solar cells and for the champion
device with the configuration ‘FTO/TiO₂/NVC-ink/Perovskite/HTM/MoO₃
(2 nm)/Au/MoO₃ (35 nm) (active area is 0.1 cm²)’, under 1 Sun illumination.
The transmittance is measured including the transparent MoO₃/Au/MoO₃ contact.

| MoO₃/Au/MoO₃ | | | | | |
|---|---|---|---|---|---|
| Au thickness | | J_{SC} | | | |
| (nm) | V_{OC} (V) | (mAcm⁻²) | FF (%) | PCE (%) | AVT (%) |
| 10 | 0.96 +/− 0.04 | 16.6 +/− 0.4 | 60.9 +/− 3 | 9.7 +/− 0.7 | 22 +/− 1 |
| | (0.99) | (17.0) | (63.2) | (10.59) | (23) |
| 20 | 0.97 +/− 0.02 | 17.1 +/− 0.7 | 63.4 +/− 3 | 10.5 +/− 0.5 | 14 +/− 1 |
| | (0.98) | (17.6) | (63.5) | (11.02) | (15) |

As expected, the 20 nm gold decreases the solar cell transparency to 14%, while the 10 nm gold provides 22% transparency. These transparencies were measured for the full solar cells stuck. The best efficiency observed for the fully semi-transparent solar cell was 10.6% with V_{oc} of 0.99V, which is very close to the case with non-transparent contact. The current-voltage curve and an image of the full solar cell including the transparent contact can be seen in FIG. 6C. Once the approach for fabricating a semi-transparent solar cell was established, we evaluated the possibility of digital control of the transparency, by changing the columns' surface density through the printing process. FIG. 6D presents the AVT and PCE as a function of the column's area fraction. As shown, the higher the columns' fraction, the higher the transparency, and the lower the PCE. Therefore, the target values of PCE and AVT can be easily controlled by the printing parameters while using the same cell structure and materials. It should be noted that the PCE is calculated for the overall cell, which contains also an in-active area (which does not include perovskite). FIG. 8 shows a schematic illustration of the calculation of the active area of the cell, while excluding the column's area. PCE calculation of the active area only (based on FIG. 8) is 15.7%, which is calculated in the following manner: the area of one NVC-ink circle is (πr²)=3.14×150² 1 m²=70,650 um² (or) 0.07065 mm². In 1 mm² area, there are 4 circles, therefore the number of ink-circles in active area-8.8 mm²×4, i.e., 35.2 circles are present. The area of 35.2 circles is (35.2×0.07065 mm²)=2.5 mm², and therefore, the normalized device active area (omitting the ink occupied area)=8.8−2.5=6.3 mm² (or) 0.063 cm². For the exemplary champion device, the measured current density is (J_{sc})=15.9 mA/cm²; therefore, the current=15.9×0.088=1.399 mA. Then, J_{sc} for the normalized area=1.399/0.063=22.2 mA/cm². PCE for the normalized area=(22.2×1.06×66.7)/100%=15.7%.

It may be argued that achieving 11% efficiency with 25% AVT is low compared to what could be expected for a cell having only a 50% of the active area. Theoretically, if one cuts out half of this cell, the V_{oc} will remain the same and the current will drop by a factor of two; therefore, the efficiency of this halved device, assuming the same area A as before, will be x/2%. If the efficiency will remain the same x/2% and if one considers the device to have the original area, therefore the device will have 50% transparency. This evaluation is correct for an ideal cell, for which the V_{oc} and the Fill Factor (FF) do not change.

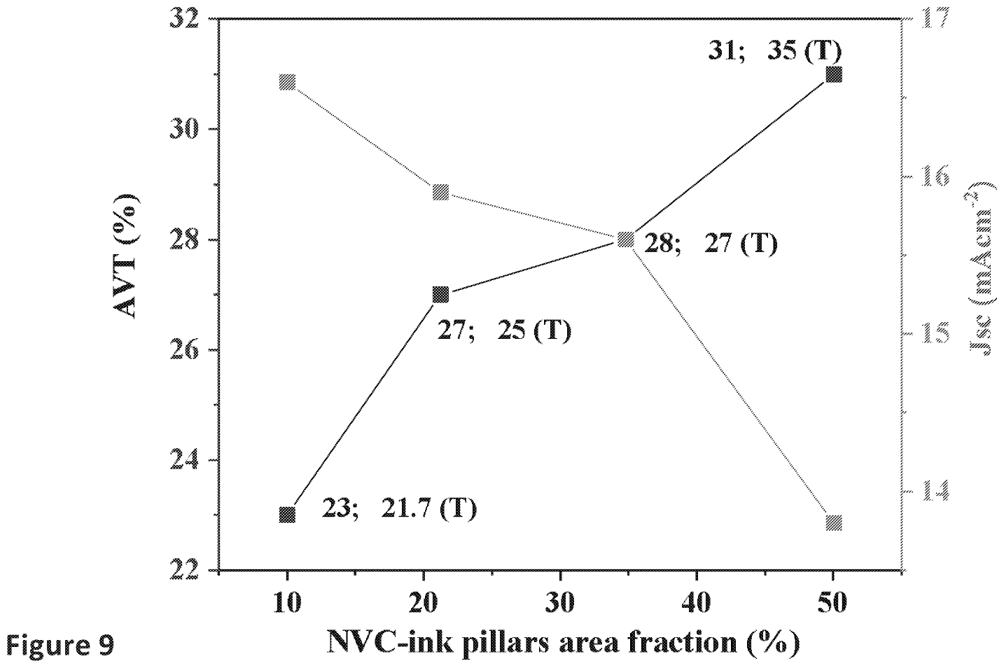

However, in order to fabricate a semi-transparent cell in which the spots of inactive area (transparent column like structures by the herein approach) are very small, in the micron range, there is an inherent problem that imparts the cell performance, namely formation of many interfaces, defects and boundaries. This leads to a significant decrease in J_{sc}. In the herein case, V_{oc} values are not affected significantly, and are around 1V, while the FF values reduced to 66% of that of a non-transparent cell. Since the current example employs the Cs_{0.2}FA_{0.8}Pb(I_{0.6}Br_{0.4})₃ perovskite composition, with an optical bandgap of Eg-1.74 eV, the maximum J_{sc} that can be generated by this perovskite is 21.1 mAcm⁻². In the semi-transparent cells the measured J_{sc} is 15.9 mAcm⁻². This value is found to be 75% (15.9/21.1=0.75) of the maximum J_{sc}, meaning a 25% reduction in J_{sc} value. Therefore, in the case of 15.9 mAcm⁻², the J_{sc} fraction % is 15.9/21.1×100=75%, and as a result, the theoretical AVT equals 100%−75%=25%, which corresponds well with the presented results. FIG. 9 and Table 4 present the measurements of AVT and J_{sc} values measured for the semi-transparent devices versus the fraction of the area of the printed polymer columns.

TABLE 4
The experimental J_{SC}, AVT and theoretically
calculated AVT values for the NVC-ink PSCs.

| Jsc | Ink pillar area | Experimental | Theoretical AVT % |
|---|---|---|---|
| (mAcm⁻²) | fraction | AVT % | (The reduced Jsc, %) |
| 16.6 | 10 | 23 | 21.7 |
| 15.9 | 21.2 | 27 | 25 |
| 15.6 | 35 | 28 | 27 |
| 13.8 | 50 | 31 | 35 |

The theoretical AVT is calculated in the following manner:
The cell with AVT zero can generate a maximum J_{sc} of 21.1 mAcm⁻², therefore for 16.6 mAcm⁻², the J_{sc}%=(16.6/21.1×100)=78.3%; the theoretical AVT is =100−78.3=21.7%.

To conclude, the inventors of the present invention have developed and investigated a new design of semi-transparent perovskite solar cell. Inkjet printing is utilized in order to print transparent column like structures or pillars which do not react with the perovskite layer. The ink is printed on top of a mesoporous TiO₂, leaving transparent spots which later on provides the transparency of the solar cell. The perovskite is spread in between said spots and further cover them with a thin overlayer. As a result, an efficient semi-transparent ink perovskite solar cell is obtained, demonstrating 11.2% efficiency with AVT of 27% without the contact. The deposition of transparent contact in which gold is sandwiched between two thin MoO₃ layers results in a solar cell with 10.6% efficiency and slightly reduced transparency, 22% AVT. Charge extraction and IMPS show the reason for these efficient semi-transparent cells, for which the recombination and electron transport time were measured. The present invention provides a utilization of inkjet printing as additive manufacturing technology for the fabrication of highly attractive semi-transparent perovskite solar cells. The use of digital printing enables to precisely control the transparency while maintains the efficiency high and thus allowing scaling the fabrication of semi-transparent PSCs.

### Experimental Details

### Materials:

All the chemicals are commercially available, procured and utilized for the experiments without further purifications. The N-Vinylcaprolactam (NVC), Diphenyl(2,4,6-trimethylbenzoyl) phosphine oxide (TPO), Triphenylphosphine, Zinc powder, Titanium diisopropoxide bis(acetylacetonate), Titanium (IV) chloride (TiCl₄) solution, Caesium iodide, Formamidinium iodide, Lead (II) iodide, Lead (II) bromide, 2,2,7,7-Tetrakis [N,N-di(4-methoxyphenyl)amino]-9,9′-spirobifluorene (Spiro-OMeTAD), 4-tert-Butylpyridine (TBP), Lithium bis-(trifluoromethylsulfonyl)imide, Hydrochloric acid, Hellmanex and anhydrous solvents like N,N-Dimethylformamide (DMF), Dimethyl sulfoxide (DMSO), Anisole, Ethanol, Isopropanol were purchased from Sigma-Aldrich (Merck). The conducting FTO/glass substrates were procured from Pilkington pvt LTD.

### Electrode Preparation:

Prior to the fabrication devices, the FTO conducting glass substrates (sheet resistance ˜25 Ωcm⁻²) were etched using Zn powder and Conc. HCl solution, obtaining a required electrode conductive patterns followed by cleaning the patterns in soap solution, hellmanex (2% in DI H₂O), acetone and isopropanol, each for 20 minutes respectively, and therefore placing the patterns in an ultrasonic bath. The pre-cleaned FTOs are treated with oxygen plasma for 5 min and then a blocking layer of TiO₂ is deposited by spin-coating (5000 rpm, 30 sec), where the Titanium diisopropoxide bis(acetylacetonate) diluted in absolute ethanol (200 μm in 1.5 mL). The substrates were calcinated at 450° C. for half an hour. After cool-down, a meso-porous TiO₂ (greatcell's product: 90T paste, diluted by 4 times in absolute ethanol) layer is deposited on the substrates using the spin-coater (5000 rpm, 30 sec), followed by annealing the substrates at 500° C. for 30 min. After reaching room temperature, these substrates were placed in aq. TiCl₄ solution (90 mM) and maintained at 75° C. for 30 minutes, followed by annealing the electrodes at 450° C. for another 30 min. These electrodes were stored in a nitrogen filled glovebox prior to completion the device fabrication.

### Ink-Preparation and Printing:

Herein we present an example of printing inks that enables printing of pillars by inkjet printing followed by rapid polymerization upon exposure to light. NVC-ink is prepared by taking the NVC monomer (4 gm), a 4 wt % photo-initiator (TPO, 0.16 gm) and 9.2 wt % surface curing agent (triphenylphosphine, 0.368 gm) into a glass vial. After shaking it well for 10 min, the solid mixture turned into a homogeneous liquid ink. The freshly prepared ink is a viscous solution, diluted further in anisole (1:2 v/v) and this is formulated ink used to fill the printer cartridge. The TiCl₄ treated substrates were placed on printer-plate, and the printing co-ordinates were noted in the software. The style for the printing pattern is loaded into the software (Dimatix). During the printing process, the cell-pitch is 700 μm and pixcel-pitch is 25 μm, both are same in X, and Y directions. Also, during the printing of ink, the printer-plate and the cartridge head were maintained at room temperature. Prior to the printing, the electrode is purged with N2 gas for the elimination of unwanted dust particles from the surface and then NVC ink was printed as shown in the scheme. After depositing a layer of ink pattern on the electrode, and without further ado, the substrates were irradiated with Ultraviolet (UV)-light for 60 seconds each time, and a total of three layers of ink were deposited on the electrode.

### Device Fabrication:

The TiO₂/Polymer-ink electrodes were brought into the N2 filled glovebox, and a 1.0M Cs_{0.2}FA_{0.8}PbI_{0.6}Br_{0.4} solution (in 9:1 DMF and DMSO, aged for overnight at 60° C.) is spin-coated (3500 rpm for 30 sec, ramp of 6 seconds); further, an anti-solvent chlorobenzene is dripped over the substrates at the end of the 15 seconds, before completion of the spin-coting. These electrodes were placed on hot plate at 100° C. for 30 min. After cooling the electrodes down to room temperature, the hole transport material (HTM) solution (Spiro-OMeTAD 54 mg in 750 μL chlobenzene+ 13.13 μL Li salt solution (52 mg lithium bis-(trifluoromethyl sulfonyl)imide in 100 μL acetonitrile)+21.6 μL TBP) is spin-coated (4500 rpm, 45 seconds). At the final stage, the Au back contacts of 70 nm (10 nm at a rate of 0.1 Å/sec followed by 60 nm at a rate of 1.1 Å/sec) thick were deposited using a thermal evaporator while maintaining the chamber at a high vacuum of 10-7 Torr.

### X-Ray Powder Diffraction Measurements (XRD):

XRD measurements for the Glass/TiO₂/NVC-Ink/perovskite substrate is performed on a D8 Advance diffractometer (Bruker AXS, Karlsruhe, Germany) with secondary Graphite monochromator, 2° Sollers slits and 0.2 mm receiving slit. The XRD patterns were recorded at room temperature within the range of 5° to 75° 2θ using CuKα radiation (λ=1.5418 Å), and the measurement conditions are: tube voltage of 40 kV, tube current of 40 mA, step-scan mode with a step size of 0.02° 20 and counting time of 1 s/step.

### Absorbance Measurements:

The UV-vis measurements for the electrodes prior to the deposition of the HTM and Au layers were recorded using the Jasco V-670 spectrophotometer. One of the cells which is without a perovskite layer was used as a reference during the measurements. The average visible transmittance (AVT) is calculated by averaging the recorded transmittance values (wavelength range of 400-800 nm).

### SEM:

The images of printed polymerized NVC-ink patterns on TiO₂ surface were taken by Scanning Electron Microscope (SEM) Zeiss Supra 55 FESEM (Carl Zeiss manufacturing company, Germany). During this measurement, the instrument is operated at 5 kV.

### High-Resolution Transmission Electron Microscopy (HR-TEM):

High angle annular dark field scanning TEM (HAADF STEM, with the accelerating voltage of 300 kV) images were captured with a probe-corrected high-resolution scanning transmission electron microscope, Themis Z, produced by Thermo Fisher Scientific. For this STEM measurement, using the focused ion beam assisted SEM (FEI Helios NanoLab 460F1 FIB-SEM), the lamella of the NVC-ink device cross-section is prepared on a thin copper grid coated with an ultrathin amorphous carbon film on holey carbon. The Elemental mapping for the cross-section of the device is performed with a Super-X EDS (energy dispersive X-ray spectroscopy) detector.

### Photovoltaic (PV) Characterizations:

A New Port system, with an Oriel I-V test station and Oriel Sol3A simulator is used for the PV measurements. The system extracted the solar cell efficiency parameters for all the devices. The Class AAA solar simulator used for spectral performance, uniformity of irradiance and temporal stability. The system has the 450W xenon lamp, and the output power matched to the AM1.5 global sunlight (100 mW/cm²) as the spectral match classification was IEC60904-9 2007, JIC C 8912, and ASTM E927-05. With the help of coupled digital source meter (Keithley model 2400), the I-V curves were extracted by applying an external bias to each cell. The pre-sweeping delay time was adjusted to 20 seconds while the voltage stop was 10 mV and the delay time was 10 ms. All the IV measurements were made by using a shadow-mask with an aperture area of 0.088 cm².

### Charge Extraction (CE):

CE measurements for NVC-ink and the perovskite-grid devices were performed using Autolab Potentiostat-Galvanostat (PGSTAT) with a FRA32M LED driver equipped with a white light source. For the data collection and analysis, Nova 1.1 software program was utilized. During the measurement, in the first step, the cell was discharged for 2 seconds in the dark followed by 2 seconds of 0.7 Sun illumination. In the following step, the light was shut down and the system held for a certain time (delay period) before reconnecting and collecting the remaining charges. The measurement has several cycles, where in each cycle there is a different delay period, ranging between 0.5 to 15 seconds.

### Intensity Modulated Photocurrent Spectroscopy (IMPS):

The IMPS measurements for NVC-ink and the perovskite-grid devices were performed using Autolab Potentiostat-Galvanostat (PGSTAT) with a FRA32M LED driver equipped with a white light source. For the transport lifetime data collection, the electrochemical impedance spectroscopy (EIS, Nyquist) plots were measured using the Nova 2.1.1 software program. The Nyquist plots were recorded each time the cell was illuminated (at short circuit conditions) with a constant white light. For these measurements, the intensity of the light is modulated between 0.1 and 0.7 Sun.

Inkjet Printing of Perovskite for Rigid Substrates Based Semitransparent PSCs with Polymer Pillars:

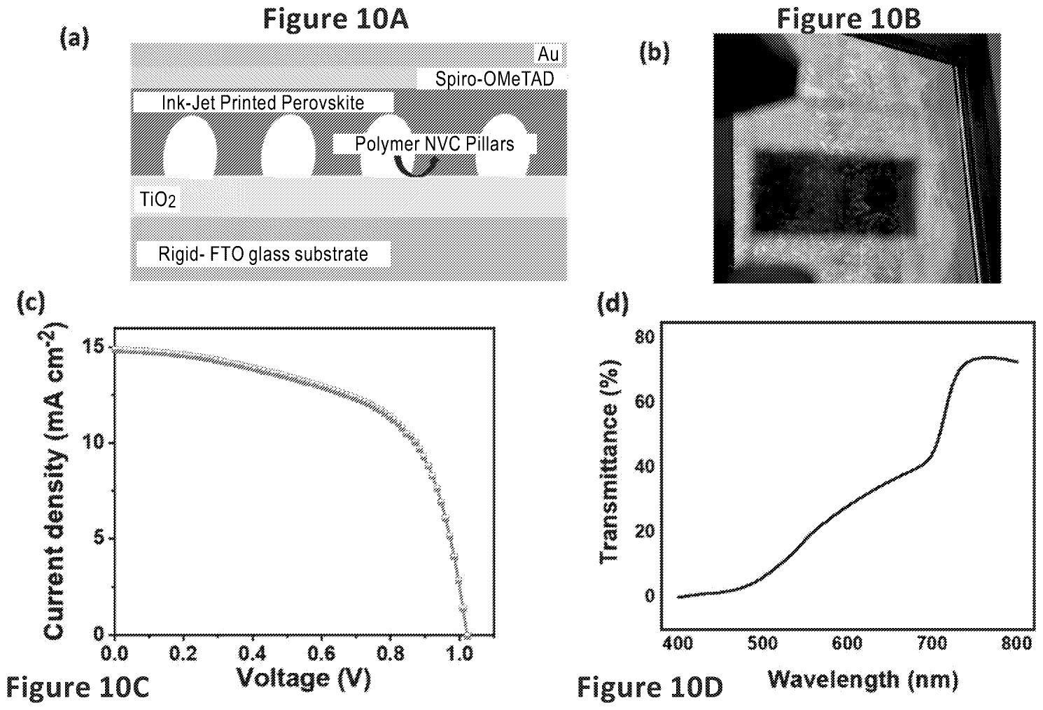

Inkjet printing involves a controlled deposition over larger areas. It consumes fewer amounts of precursor solution when compared to the spin-coating method that is exemplified above. A device fabricated by inkjet printing, demonstrated a PCE value 9%, whereas the AVT of the device was 30% measured without the top metal electrode (FIG. 10).

Inkjet Printing of Perovskite for Flexible Substrates Based Semitransparent PSC with Polymer Pillars:

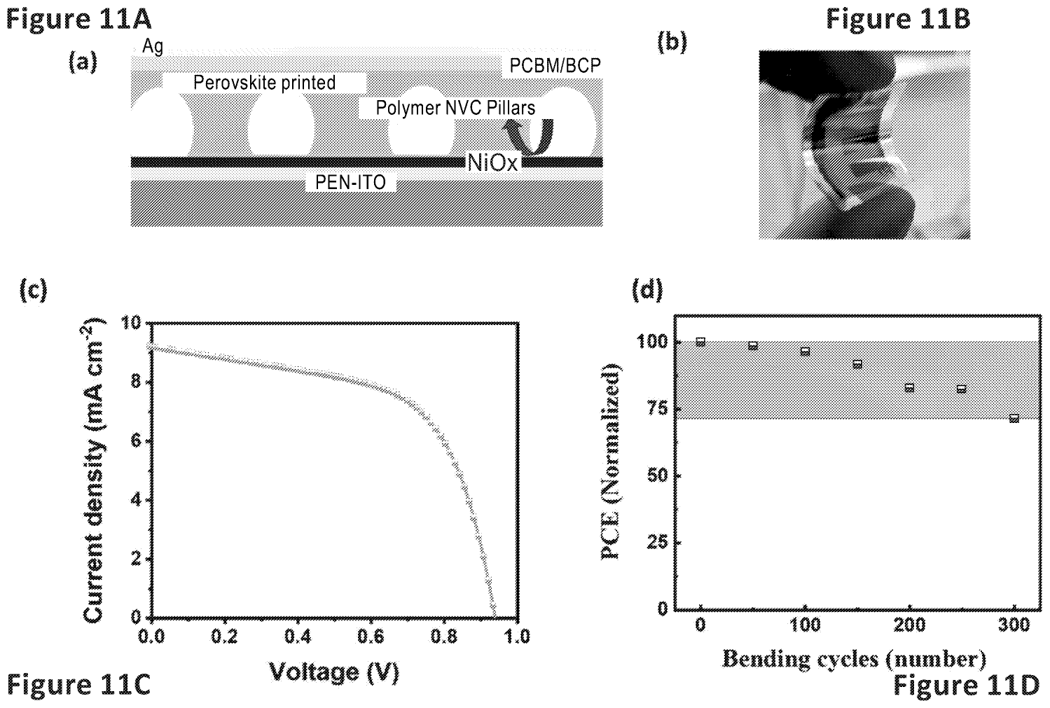

Inkjet printing of flexible solar cells according to the invention was used as a low-temperature processing of flexible polymer substrates. Planar and inverted solar cell structure were manufacture as shown in FIG. 11. The primary results of PCE, AVT and the PCE versus the number of bending cycles obtained for the flexible semitransparent PSCs are provided below.

TABLE 5
The PCE parameters obtained for the rigid solar cell
(Glass/FTO/TiO2/Polymer (NVC)-polymer ink pillars/Perovskite/Spiro-
OmeTAD/Au: solar cell active area 0.1 cm²) under 1
SUN illumination using a AAA class solar simulator.
(The transmittance is measured for the device without
the top metal contact.)

| Cell | | | | | |
|---|---|---|---|---|---|
| Structure | Voc (V) | Jsc (mAcm²) | FF (%) | Eff (%) | AVT (%) |
| Rigid | 1.02 | 14.8 | 59.8 | 9.05 | 30% |
| Cell | | | | | |
| Structure | Voc (V) | Jsc (mAcm2) | FF (%) | Eff (%) | AVT (%) |
| Flexible | 0.94 | 9.24 | 59.65 | 5.17 | 32% |

Table 6: The PCE parameters obtained for the rigid solar cell (PEN/ITO/NiOx/Polymer (NVC)-ink pillars/Perovskite/PCBM/BCP/Ag: solar cell active area 0.1 cm²) under 1 SUN illumination using a AAA class solar simulator. (The transmittance is measured for the device without the top metal contact.)

### Experimental Details

Materials: All chemicals are commercially available, procured, and used for the experiments without further purifications: N-vinyl caprolactam (NVC: 98%, Sigma-Aldrich), diphenyl(2,4,6-trimethyl benzoyl) phosphine oxide (TPO: BASF, Germany), triphenylphosphine (99%, Strem Chemicals), zinc dust (<10 μm, >98%, Sigma-Aldrich), cesium iodide (CsI: 99.999%, Sigma-Aldrich), formamidinium iodide (FAI: 99.99%, Sigma-Aldrich), lead (II) iodide (PbI₂: 99%, Sigma Aldrich), lead (II) bromide (PbBr₂: >98%, Sigma-Aldrich), hydrochloric acid (37%, Sigma-Aldrich), Hellmanex (Sigma-Aldrich), and anhydrous solvents like N,N-dimethylformamide (DMF: 99.8%, Acros Organics), dimethyl sulfoxide (DMSO: 99.7+%, Acros Organics), anisole (99.7%, Sigma-Aldrich), ethanol (99%, Fisher Scientific, U.K.), and isopropanol (>99.7%, Daejung Chemicals-Korea). The conducting PEN/ITO substrates (15 ohm/sq) were procured from Peccell (Japan).
NiOx synthesis: Nickel Oxide (NiOx) is synthesized by following a previous report. In brief, Ni(NO₃)_{2.6}H₂O (3 gm) dissolved in 120 mL of deionized water (DI-H₂O) and stirred to get a clear green solution. The pH of this solution is adjusted to 10 by the addition of 1M NaOH and the obtained green precipitate is washed 3 times with DI H₂O to remove the reactants and then dried in a vacuum oven at 70° C. (overnight). The obtained green pellets were calcinated at 275° C. for 2 hrs, and finally received the dark grey pellets and labelled as NiOx, after grinding, dispersed into 10% IPA/DI H₂O and used as hole transport material for solar cell fabrication.
Perovskite precursor solution: 0.9M Perovskite (Cs_{0.2}FA_{0.8}PbI_{0.6}Br_{0.4}) solution is prepared by the addition of CsI (46.73 mg), FAI (123.84 mg), PbI₂ (249.48 mg), and PbBr₂ (132.14 mg) into a vial with 0.9 mL DMF, and 0.1 mL PM. The Perovskite solution is stirred for 4 hrs at 70° C., and to this solution, after cooling to room temperature, Triton X-114 surfactant (0.03 Wt. % using a pre-diluted surfactant solution of DMF) is added. This solution, after the addition of surfactant, is stirred (800 rotations per min., at 70° C.) for 5 min. and filtered (filter pore dia. 0.4 μm) before filling into the printer's cartridge.
Solar cell fabrication: Prior to the solar cell fabrication, the flexible PEN/ITO substrates with the required dimensions were cleaned in an ultrasonic bath using a soap solution, Acetone, and Ethanol for 10 min each, these substrates are treated with O₂ plasma (30%, 90 sec). 15 mg NiOx powder is well dispersed in 10% IPA (1 mL) by placing it in the bath sonication for 2 hrs maintaining the temperature below 35° C. and deposited onto the plasma-treated PEN-ITO substrates without further delay, followed by heated placing then on to a hot plate (100° C., 15 min). The NVC monomer ink is printed and polymerized by Ultraviolet (UV) light (constant illumination for 60 sec with a centre wavelength of 395 nm with an intensity of 50 mW/cm²). Then the perovskite solution is printed and then vented under the vacuum chamber (a homemade) for the initiation of perovskite crystallization. Then the substrates are placed onto a hot plate (100 C, 30 min), in an open-air atmosphere to complete the perovskite crystallization. Then PCBM (1 mg/1 mL Chlorobenzene, 100 μL) and BCP (1 mg/1 mL Ethanol, 200 μL) are spin-coated at 1500 and 5000 r.p.m., respectively. At the end, a 100 nm thick Ag layer is deposited by a thermal evaporator in three steps.

1-52. (canceled)

53. A perovskite film comprising spaced-apart islands of at least one functionalizable polymeric material, wherein the islands are free of a perovskite material, and having a length/height being at least a thickness of the film, wherein the film is transparent or semitransparent.

54. The film according to claim 53, wherein the spaced-apart islands are features of the at least one functionalizable polymeric material being substantially 3-dimensional in shape.

55. The film according to claim 53, wherein the film having an average visible transmittance (AVT) of at least about 12% or 20%.

56. A device comprising or implementing a perovskite film according to claim 53.

57. The device according to claim 56, being a multilayered or stacked device, wherein the perovskite film is a topmost layer or an inner layer.

58. The device according to claim 56, wherein islands formed in the perovskite film extend the surface of the film and penetrate into adjacent material layers.

59. The device according to claim 56, comprising an FTO electrode, an electron transport layer (ETL), a mesoporous oxide layer, a perovskite layer, a hole transport layer (HTL) and an electrode layer.

60. The device according to claim 56, the device having the structure HTL/perovskite/ETL/metal contact, wherein “HTL” is a hole transport material layer, “Perovskite” is a perovskite material, “ETL” is an electron transport material layer, and “Metal contact” is a physical contact made of a metallic material.

61. The device according to claim 56, wherein the device comprises a substrate, a compact metal oxide layer and a mesoporous metal oxide layer, wherein the perovskite film is provided on the mesoporous metal oxide layer.

62. A process for fabricating a film according to claim 53, the process comprises forming spaced-apart islands or pillar features of at least one functionalizable polymeric material on a surface region of a substrate and coating regions of the surface region not coated with the at least one functionalizable polymeric material with at least one perovskite material.

63. The process according to claim 62, wherein forming the spaced-apart islands or regions comprises depositing on the surface region a polymer precursor or a polymerizable material and causing said polymer precursor or polymerizable material to convert into the at least one functionalizable polymeric material.

64. The process according to claim 63, wherein the deposition of the polymer precursor or the polymerizable material and optionally of a photoinitiator onto a surface region to pattern the surface with spaced-apart polymeric pillars is achieved by a patterning device.

65. A transparent or a semitransparent photovoltaic cell device comprising a perovskite film and a plurality of spaced-apart islands or pillars of at least one functionalizable polymeric material embedded within a plurality of material layers making up the device and extending the thickness of the device from a substrate of the device.

66. The device according to claim 65, wherein each of the pillars extends the thickness of the multilayered device from a substrate of said device.

67. The device according to claim 65, the device comprising an FTO electrode, an electron transport layer (ETL), a mesoporous oxide layer, a perovskite layer, a hole transport layer (HTL) and an electrode layer.

68. The device according to claim 67, having the structure HTL/perovskite/ETL/metal contact, wherein “HTL” is a hole transport material layer, “Perovskite” is a perovskite material, “ETL” is an electron transport material layer, and “Metal contact” is a physical contact made of a metallic material.

69. The device according to claim 65, wherein the perovskite film is provided as a perovskite layer of a material selected from
Cs₁₋ₓFAₓPb(I_{1-y}Br_{y})₃, wherein each of x and y, independently, is between 0 and 1; or, each of x an y, independently, is between 0 and 1, but is not zero;
Cs_{0.2}FA_{0.8}Pb(I_{0.6}Br_{0.4})₃;
Cs_{0.15}FA_{0.75}MA_{0.10}PbI₂Br;
Cs_{0.15}FA_{0.85}PbI₂Br;
FAₓMAₓ₋₁Y, wherein Y is the perovskite species and wherein 0<=x<=1;
FA_{0.85}MA_{0.15}PbI₃;
FA_{0.85}MA_{0.15}PbI₂Br;
FA_{0.85}MA_{0.15}PbIBr₂;
wherein FA is formamidine and MA is methylamine.

70. The device according to claim 69, wherein the perovskite material is Cs_{0.2}FA_{0.8}Pb(I_{0.6}Br_{0.4})₃; Cs_{0.15}FA_{0.75}MA_{0.10}PbI₂Br; Cs_{0.15}FA_{0.85}PbI₂Br; FA_{0.85}MA_{0.15}PbI₃; FA_{0.85}MA_{0.15}PbI₂Br; or FA_{0.85}MA_{0.15}PbIBr₂; wherein FA is formamidine and MA is methylamine.

71. The device according to claim 65 having an average visible transmittance (AVT) value between 12 and 35% or between 35 and 80%.

72. A photovoltaic cell device comprising a perovskite film of a material selected from Cs_{0.2}FA_{0.8}Pb(I_{0.6}Br_{0.4})₃; Cs_{0.15}FA_{0.75}MA_{0.10}PbI₂Br; Cs_{0.15}FA_{0.85}PbI₂Br; FA_{0.85}MA_{0.15}PbI₃; FA_{0.85}MA_{0.15}PbI₂Br; or FA_{0.85}MA_{0.15}PbIBr₂; wherein FA is formamidine and MA is methylamine; and a plurality of spaced-apart pillars of at least one functionalizable polymeric material embedded within a plurality of material layers and extending the thickness of the device from a substrate of the device, wherein the material layers comprise an electron transport layer (ETL), a mesoporous oxide layer, a perovskite layer, and a hole transport layer (HTL).
